(19) United States
(12) Patent Application Publication
(10) Pub. No.: US 2018/0205257 A1
(43) Pub. Date: Jul. 19, 2018

(54) WIRELESS POWER TRANSMITTER AND VEHICLE CONTROL UNIT CONNECTED THERETO

(71) Applicant: LG INNOTEK CO., LTD., Seoul (KR)

(72) Inventors: YONG IL KWON, Seoul (KR); JAE KYU LEE, Seoul (KR)

(73) Assignee: LG INNOTEK CO., LTD., Seoul (KR)

(21) Appl. No.: 15/743,981

(22) PCT Filed: Aug. 17, 2016
(86) PCT No.: PCT/KR2016/009011

§ 371 Date: Jan. 11, 2018

(30) Foreign Application Priority Data
Aug. 17, 2015 (KR) 10-2015-0115255

(51) Int. Cl. H02J 7/02; H05K 7/20; H02J 50/12; H02J 5/00

(52) U.S. Cl. CPC H02J 7/025; H05K 7/20; H02J 5/005; H02J 50/12; H02J 7/027

(57) ABSTRACT

The present invention relates to a wireless charging technology and, more particularly, to a wireless power transmitter and a vehicle control unit connected thereto, which can check information on a wireless charging operation using an in-vehicle system when the wireless charging operation is performed within a vehicle. A vehicle control unit according to an embodiment of the present invention may be connected to at least one of a wireless power transmitter and a wireless power receiver which perform a wireless charging operation, and may display a message corresponding to status of charge information generated on the basis of status detection information associated with the wireless charging operation. Therefore, a variety of information associated with a wireless charging operation is output through the vehicle control unit, so that a user can more safely and quickly recognize and cope with various changes in the status of charge, which may occur in a vehicle driving environment.

### TECHNICAL FIELD

Embodiments relate to wireless charging technology, and more particularly, to a wireless power transmitter capable of checking information on a wireless charging operation using a system of a vehicle when the wireless charging operation is performed in the vehicle, and a vehicle control unit connected thereto.

### BACKGROUND ART

Recently, as information and communication technology rapidly develops, a ubiquitous society based on information and communication technology is being formed.

In order for information communication devices to be connected anywhere and anytime, sensors equipped with a computer chip having a communication function should be installed in all facilities throughout society. Accordingly, power supply to these devices or sensors is becoming a new challenge. In addition, as the types of mobile devices such as Bluetooth handsets and iPods, as well as mobile phones, rapidly increase in number, charging the battery has required time and effort. As a way to address this issue, wireless power transmission technology has recently drawn attention.

Wireless power transmission (or wireless energy transfer) is a technology for wirelessly transmitting electric energy from a transmitter to a receiver using the induction principle of a magnetic field. Back in the 1800s, an electric motor or a transformer based on the electromagnetic induction principle began to be used. Thereafter, a method of transmitting electric energy by radiating an electromagnetic wave such as a radio wave or laser was tried. Electric toothbrushes and some wireless shavers are charged through electromagnetic induction.

Up to now, wireless energy transmission schemes may be broadly classified into electromagnetic induction, electromagnetic resonance, and RF transmission using a short-wavelength radio frequency.

In the electromagnetic induction scheme, when two coils are arranged adjacent to each other and current is applied to one of the coils, a magnetic flux generated at this time generates electromotive force in the other coil. This technology is being rapidly commercialized mainly for small devices such as mobile phones. In the electromagnetic induction scheme, power of up to several hundred kilowatts (kW) may be transmitted with high efficiency, but the maximum transmission distance is less than or equal to 1 cm. As a result, the device should be generally arranged adjacent to the charger or the floor.

The electromagnetic resonance scheme uses an electric field or a magnetic field instead of using an electromagnetic wave or current. The electromagnetic resonance scheme is advantageous in that the scheme is safe to other electronic devices or the human body since it is hardly influenced by the electromagnetic wave. However, this scheme may be used only at a limited distance and in a limited space, and has somewhat low energy transfer efficiency.

The short-wavelength wireless power transmission scheme (simply, RF transmission scheme) takes advantage of the fact that energy can be transmitted and received directly in the form of radio waves. This technology is an RF power transmission scheme using a rectenna. A rectenna, which is a compound of antenna and rectifier, refers to a device that converts RF power directly into direct current (DC) power. That is, the RF method is a technology for converting AC radio waves into DC waves. Recently, with improvement in efficiency, commercialization of RF technology has been actively researched.

The wireless power transmission technology is applicable to various industries including IT, railroads, and home appliance industries as well as the mobile industry.

In addition, there is growing interest in availability of wireless power transmission technology in a vehicle, but the specificity of the vehicle traveling environment (for example, shaking of the vehicle body) should be taken into account in applying wireless power transmission technology to vehicles.

### DISCLOSURE

### Technical Problem

Therefore, the present disclosure has been made in view of the above problems, and embodiments provide a wireless power transmitter and a vehicle control unit connected thereto.

Further, embodiments provide a wireless power transmitter allowing a user to easily check information related to a wireless charging operation performed in a vehicle driving environment, and a vehicle control unit connected thereto.

Further, embodiments provide a wireless power transmitter capable of providing an interface for monitoring and controlling a plurality of wireless power receivers participating in a wireless charging operation, and a vehicle control unit connected thereto.

The technical objects that can be achieved through the embodiments are not limited to what has been particularly described hereinabove and other technical objects not described herein will be more clearly understood by persons skilled in the art from the following detailed description.

### Technical Solution

In one embodiment, a vehicle control unit may be connected to at least one of a wireless power transmitter performing a wireless charging operation or a wireless power receiver, and display a message corresponding to charging state information generated based on state sensing information related to the wireless charging operation.

In one embodiment, the state sensing information may include total power capacity information, remaining power capacity information and load receive power information about a load of the wireless power receiver, wherein the charging state information may include estimated charging completion time information indicating an estimated time at which charging of the wireless power receiver is completed, the estimated charging completion time information being calculated based on the total power capacity information, the remaining power capacity information, and the load receive power information.

In one embodiment, the state sensing information may include channel setting result information and an impedance change, the channel setting result information being information on whether a feedback signal is received by transmitting a signal for channel setting, wherein the charging state information may include foreign matter sensing information indicating corresponding to the channel setting result information indicating that the feedback signal has not been received even though the impedance change has occurred.

In one embodiment, the state sensing information may include transmit power information about the wireless power transmitter and current receive power information about the wireless power receiver, wherein the charging state information may include array correction information, the array correction information being generated when a ratio of the current receive power information to the transmit power information is out of a normal range.

In one embodiment, the state sensing information may include temperature info illation about the wireless power transmitter, wherein the charging state information may include abnormal temperature information, the abnormal temperature information being generated when a temperature of the wireless power receiver according to the temperature information is out of a normal temperature range.

In one embodiment, when the abnormal temperature information is received, the vehicle control unit may activate a cooling unit configured to reduce the temperature of the wireless power receiver according to the abnormal temperature information.

In one embodiment, when the temperature of the wireless power receiver returns to the normal temperature range, the vehicle control unit may stop operation of the cooling unit.

In one embodiment, the state sensing information may include charging start information generated when connection between the wireless power transmitter and the wireless power receiver is established, wherein the charging state information may include charging connection information generated based on the charging start information and receiver identification information about the wireless power receiver.

In one embodiment, the charging state information may be generated by the wireless power transmitter based on the state sensing information provided by wireless power receiver and received from the wireless power transmitter.

In one embodiment, the charging state information may be generated by the vehicle control unit based on the state sensing information received from the wireless power receiver.

In one embodiment, the charging state information may be generated by and received from the wireless power receiver.

In another embodiment, a vehicle control unit connected to at least one of a wireless power transmitter performing a wireless charging operation or a plurality of wireless power receivers, wherein the vehicle control unit displays a message corresponding to charging state information generated based on state sensing information related to the wireless charging operation.

In another embodiment, a vehicle control unit may be connected to at least one of a wireless power transmitter performing a wireless charging operation or a wireless power receiver, and display a message corresponding to charging state information generated based on state sensing information related to the wireless charging operation, wherein the vehicle control unit may be connected to the wireless power receiver in a short-range communication scheme.

In another embodiment, a vehicle control unit may be connected to at least one of a wireless power transmitter performing a wireless charging operation or a plurality of wireless power receivers, and display a message corresponding to charging state information generated based on state sensing information related to the wireless charging operation, wherein the vehicle control unit may be connected to the wireless power receivers in a short-range communication scheme.

In one embodiment, a wireless power transmitter may be configured to generate charging state information based on state sensing information related to a wireless charge operation performed on a wireless power receiver and to transmit the charging state information to a vehicle control unit such that a message corresponding to the charging state information is displayed.

The above-described aspects of the present disclosure are merely a part of preferred embodiments of the present disclosure. Those skilled in the art will derive and understand various embodiments reflecting the technical features of the present disclosure from the following detailed description of the present disclosure.

### Advantageous Effects

The method and apparatus according to the embodiments have the following effects.

In a wireless charging system according to an embodiment, as various kinds of information related to the wireless charging operation are output through a vehicle control unit, a user may more safely and promptly recognize and cope with various changes in charging state that may occur in a travel environment of a vehicle.

In addition, even when a plurality of portable devices is charged, the wireless charging state of a plurality of portable devices may be monitored and controlled.

In addition, through direct communication between the vehicle control unit and the wireless power receiver, it is possible to provide a wider variety of information to the vehicle control unit.

It will be appreciated by those skilled in the art that that the effects that can be achieved through the embodiments of the present disclosure are not limited to those described above and other advantages of the present disclosure will be more clearly understood from the following detailed description.

### DESCRIPTION OF DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a system configuration diagram illustrating a wireless power transmission method using an electromagnetic resonance scheme according to an embodiment of the present disclosure;

FIG. 2 is a diagram illustrating a type and characteristics of a wireless power transmitter in an electromagnetic resonance scheme according to an embodiment of the present disclosure;

FIG. 3 is a diagram illustrating a type and characteristics of a wireless power receiver in an electromagnetic resonance scheme according to an embodiment of the present disclosure;

FIG. 4 shows equivalent circuit diagrams of a wireless power transmission system in an electromagnetic resonance scheme according to an embodiment of the present disclosure;

FIG. 5 is a state transition diagram illustrating a state transition procedure of a wireless power transmitter in an electromagnetic resonance scheme according to an embodiment of the present disclosure;

FIG. 6 is a state transition diagram illustrating a state transition procedure of a wireless power receiver in an electromagnetic resonance scheme according to an embodiment of the present disclosure;

FIG. 7 illustrates operation regions of a wireless power receiver according to VRECT in an electromagnetic resonance scheme according to an embodiment of the present disclosure;

FIG. 8 is a diagram illustrating a wireless charging system of an electromagnetic induction scheme according to an embodiment of the present disclosure;

FIG. 9 is a state transition diagram of a wireless power transmitter supporting an electromagnetic induction scheme according to an embodiment of the present disclosure;

FIG. 10 is a block diagram illustrating a structure of a wireless charging system according to an embodiment of the present disclosure;

FIG. 11 is a view illustrating a position where the wireless power transmitter shown in FIG. 10 is installed in a vehicle;

FIG. 12 is a block diagram illustrating an embodiment of the wireless charging system shown in FIG. 10;

FIGS. 13 to 19 illustrate an example of messages that may be displayed on a display unit;

FIG. 20 is a block diagram illustrating another embodiment of the wireless charging system shown in FIG. 10;

FIGS. 21 to 22 illustrate an example of messages that may be displayed on a display unit;

FIG. 23 is a block diagram illustrating another embodiment of the wireless charging system shown in FIG. 10; and

FIGS. 24 and 25 illustrate an example of messages that may be displayed on a display unit.

### BEST MODE

A vehicle control unit according to a first embodiment of the present disclosure may be connected to at least one of a wireless power transmitter and a wireless power receiver that perform a wireless charging operation and display a message corresponding to charge state information generated based on state sensing information related to the wireless charging operation.

### MODE FOR INVENTION

Hereinafter, an apparatus and various methods to which embodiments of the present disclosure are applied will be described in detail with reference to the drawings. As used herein, the suffixes “module” and “unit” are added or used interchangeably to facilitate preparation of this specification and are not intended to suggest distinct meanings or functions.

While all elements constituting embodiments of the present disclosure have been described as being connected into one body or operating in connection with each other, the disclosure is not limited to the described embodiments. That is, within the scope of the present disclosure, one or more of the elements may be selectively connected to operate. In addition, although all elements can be implemented as one independent hardware device, some or all of the elements may be selectively combined to implement a computer program having a program module for executing a part or all of the functions combined in one or more hardware devices. Code and code segments that constitute the computer program can be easily inferred by those skilled in the art. The computer program may be stored in a computer-readable storage medium, read and executed by a computer to implement an embodiment of the present disclosure. The storage medium of the computer program may include a magnetic recording medium, an optical recording medium, and a carrier wave medium.

In the description of the embodiments, it is to be understood that when an element is described as being “on” or “under” and “before” or “after” another element, it can be “directly” “on” or “under” and “before” or “after” another element or can be “indirectly” formed such that one or more other intervening elements are also present between the two elements.

The terms “include,” “comprise” and “have” should be understood as not precluding the possibility of existence or addition of one or more other components unless otherwise stated. All terms, including technical and scientific terms, have the same meaning as commonly understood by one of ordinary skill in the art to which this disclosure pertains, unless otherwise defined. Commonly used terms, such as those defined in typical dictionaries, should be interpreted as being consistent with the contextual meaning of the relevant art, and are not to be construed in an ideal or overly formal sense unless expressly defined to the contrary.

In describing the components of the present disclosure, terms such as first, second, A, B, (a), and (b) may be used. These terms are used only for the purpose of distinguishing one constituent from another, and the terms do not limit the nature, order or sequence of the components. When one component is said to be “connected,” “coupled” or “linked” to another, it should be understood that this means the one component may be directly connected or linked to another one or another component may be interposed between the components.

In the description of the embodiments, “wireless power transmitter,” “wireless power transmission device,” “transmission terminal,” “transmitter,” “transmission device,” “transmission side,” and the like will be interchangeably used to refer to a device for transmitting wireless power in a wireless power system, for simplicity.

In addition, “wireless power reception device,” “wireless power receiver,” “reception terminal,” “reception side,” “reception device,” “receiver,” and the like will be interchangeably used to refer to a device for receiving wireless power from a wireless power transmission device, for simplicity.

The wireless power transmitter according to the present disclosure may be configured as a pad type, a cradle type, an access point (AP) type, a small base station type, a stand type, a ceiling embedded type, a wall-mounted type, a vehicle embedded type, a vehicle resting type, or the like. One transmitter may transmit power to a plurality of wireless power reception devices at the same time.

To this end, the wireless power transmitter may provide at least one wireless power transmission scheme, including, for example, an electromagnetic induction scheme, an electromagnetic resonance scheme, and the like.

For example, for the wireless power transmission schemes, various wireless power transmission standards based on an electromagnetic induction scheme for charging using an electromagnetic induction principle in which a magnetic field is generated in a power transmission terminal coil and electricity is induced in a reception terminal coil by the influence of the magnetic field may be used. Here, the electromagnetic induction type wireless power transmission standards may include an electromagnetic induction type wireless charging technique defined in a Wireless Power Consortium (WPC) technique or a Power Matters Alliance (PMA) technique.

In another example, a wireless power transmission scheme may employ an electromagnetic resonance scheme in which a magnetic field generated by a transmission coil of a wireless power transmitter is tuned to a specific resonant frequency and power is transmitted to a wireless power receiver located at a short distance therefrom. For example, the electromagnetic resonance scheme may include a resonance type wireless charging technique defined in Alliance for Wireless Power (A4WP), which is a wireless charging technology standard organization.

In another example, a wireless power transmission scheme may employ an RF wireless power transmission scheme in which low power energy is transmitted to a wireless power receiver located at a remote location over an RF signal.

In another example of the present disclosure, the wireless power transmitter according to the present disclosure may be designed to support at least two wireless power transmission schemes among the electromagnetic induction scheme, the electromagnetic resonance scheme, and the RF wireless power transmission scheme.

In this case, the wireless power transmitter may determine not only a wireless power transmission scheme that the wireless power transmitter and the wireless power receiver are capable of supporting, but also a wireless power transmission scheme which may be adaptively used for the wireless power receiver based on the type, state, required power, etc. of the wireless power receiver.

A wireless power receiver according to an embodiment of the present disclosure may be provided with at least one wireless power transmission scheme, and may simultaneously receive wireless power from two or more wireless power transmitters. Here, the wireless power transmission scheme may include at least one of the electromagnetic induction scheme, the electromagnetic resonance scheme, and the RF wireless power transmission scheme.

The wireless power receiver according to the present disclosure may be embedded in small electronic devices such as a mobile phone, a smartphone, a laptop computer, a digital broadcast terminal, a PDA (Personal Digital Assistant), a PMP (Portable Multimedia Player), a navigation system, an MP3 player, an electric toothbrush, an electronic tag, a lighting device, a remote control, a fishing float, and the like. However, embodiments are not limited thereto, and the wireless power receiver may be applied to any devices which may be provided with the wireless power receiving means according to the present disclosure and be charged through a battery. A wireless power receiver according to another embodiment of the present disclosure may be mounted on a vehicle, an unmanned aerial vehicle, a drone, and the like.

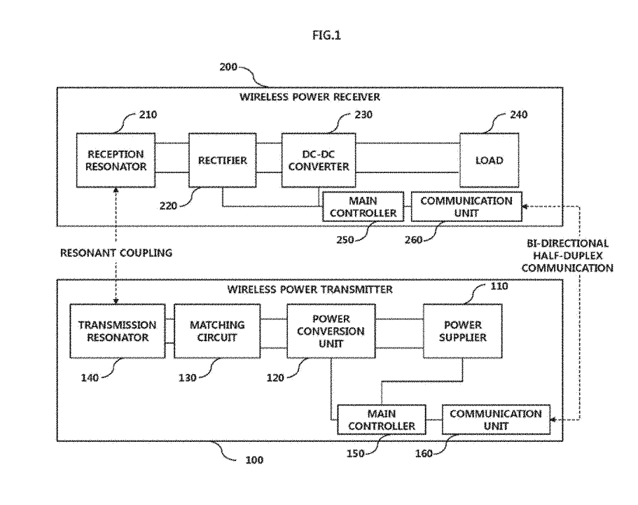

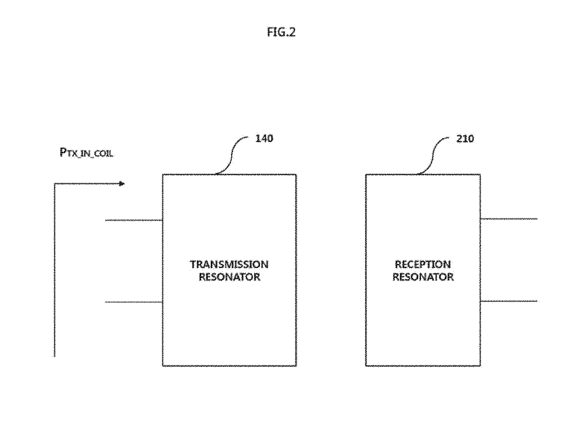

FIG. 1 is a system configuration diagram illustrating a wireless power transmission method using an electromagnetic resonance scheme according to an embodiment of the present disclosure.

Referring to FIG. 1, a wireless power transmission system may include a wireless power transmitter 100 and a wireless power receiver 200.

While FIG. 1 illustrates that the wireless power transmitter 100 transmits wireless power to one wireless power receiver 200, this is merely one embodiment, and the wireless power transmitter 100 according to another embodiment of the present disclosure may transmit wireless power to a plurality of wireless power receivers 200. It should be noted that the wireless power receiver 200 according to yet another embodiment may simultaneously receive wireless power from a plurality of wireless power transmitters 100.

The wireless power transmitter 100 may generate a magnetic field using a specific power transmission frequency (for example, a resonant frequency) to transmit power to the wireless power receiver 200.

The wireless power receiver 200 may receive power by tuning to the same frequency as the power transmission frequency used by the wireless power transmitter 100.

As an example, the frequency used for power transmission may be, but is not limited to, a 6.78 MHz band.

That is, the power transmitted by the wireless power transmitter 100 may be communicated to the wireless power receiver 200 that is in resonance with the wireless power transmitter 100.

The maximum number of wireless power receivers 200 capable of receiving power from one wireless power transmitter 100 may be determined based on the maximum transmit power level of the wireless power transmitter 100, the maximum power reception level of the wireless power receiver 200, and the physical structures of the wireless power transmitter 100 and the wireless power receiver 200.

The wireless power transmitter 100 and the wireless power receiver 200 can perform bidirectional communication in a frequency band different from the frequency band for wireless power transmission, i.e., the resonant frequency band. As an example, bidirectional communication may employ, without being limited to, a half-duplex Bluetooth low energy (BLE) communication protocol.

The wireless power transmitter 100 and the wireless power receiver 200 may exchange the characteristics and state information on each other including, for example, power negotiation information for power control via bidirectional communication.

As an example, the wireless power receiver 200 may transmit predetermined power reception state information for controlling the level of power received from the wireless power transmitter 100 to the wireless power transmitter 100 via bidirectional communication. The wireless power transmitter 100 may dynamically control the transmit power level based on the received power reception state information. Thereby, the wireless power transmitter 100 may not only optimize the power transmission efficiency, but also provide a function of preventing load breakage due to overvoltage, a function of preventing power from being wasted due to under-voltage, and the like.

The wireless power transmitter 100 may also perform functions such as authenticating and identifying the wireless power receiver 200 through bidirectional communication, identifying incompatible devices or non-rechargeable objects, identifying a valid load, and the like.

Hereinafter, a wireless power transmission process according to the resonance scheme will be described in more detail with reference to FIG. 1.

The wireless power transmitter 100 may include a power supplier 110, a power conversion unit 120, a matching circuit 130, a transmission resonator 140, a main controller 150, and a communication unit 160. The communication unit may include a data transmitter and a data receiver.

The power supplier 110 may supply a specific supply voltage to the power conversion unit 120 under control of the main controller 150. The supply voltage may be a DC voltage or an AC voltage.

The power conversion unit 120 may convert the voltage received from the power supplier 110 into a specific voltage under control of the main controller 150. To this end, the power conversion unit 120 may include at least one of a DC/DC converter, an AC/DC converter, and a power amplifier.

The matching circuit 130 is a circuit that matches impedances between the power conversion unit 120 and the transmission resonator 140 to maximize power transmission efficiency.

The transmission resonator 140 may wirelessly transmit power using a specific resonant frequency according to the voltage applied from the matching circuit 130.

The wireless power receiver 200 may include a reception resonator 210, a rectifier 220, a DC-DC converter 230, a load 240, a main controller 250 and a communication unit 260. The communication unit may include a data transmitter and a data receiver.

The reception resonator 210 may receive power transmitted by the transmission resonator 140 through the resonance effect.

The rectifier 220 may function to convert the AC voltage applied from the reception resonator 210 into a DC voltage.

The DC-DC converter 230 may convert the rectified DC voltage into a specific DC voltage required by the load 240.

The main controller 250 may control the operation of the rectifier 220 and the DC-DC converter 230 or may generate the characteristics and state information on the wireless power receiver 200 and control the communication unit 260 to transmit the characteristics and state information on the wireless power receiver 200 to the wireless power transmitter 100. For example, the main controller 250 may monitor the intensities of the output voltage and current from the rectifier 220 and the DC-DC converter 230 to control the operation of the rectifier 220 and the DC-DC converter 230.

The intensity information on the monitored output voltage and current may be transmitted to the wireless power transmitter 100 through the communication unit 260.

In addition, the main controller 250 may compare the rectified DC voltage with a predetermined reference voltage and determine whether the voltage is in an overvoltage state or an under-voltage state. When a system error state is sensed as a result of the determination, the controller 250 may transmit the sensed result to the wireless power transmitter 100 through the communication unit 260.

When the system error state is sensed, the main controller 250 may control the operation of the rectifier 220 and the DC-DC converter 230 or control the power applied to the load 240 using a predetermined overcurrent interruption circuit including a switch and/or a Zener diode, in order to prevent the load from being damaged.

In FIG. 1, the main controller 150 or 250 and the communication unit 160 or 260 of each of the transmitter and the receiver are shown as being configured as different modules, but this is merely one embodiment. It is to be noted that the main controller 150 or 250 and the communication unit 160 or 260 may be configured as a single module.

When an event such as addition of a new wireless power receiver to a charging area during charging, disconnection of a wireless power receiver that is being charged, completion of charging of the wireless power receiver, or the like is sensed, the wireless power transmitter 100 according to an embodiment of the present disclosure may perform a power redistribution procedure for the remaining wireless power receivers to be charged. The result of power redistribution may be transmitted to the connected wireless power receiver(s) via out-of-band communication.

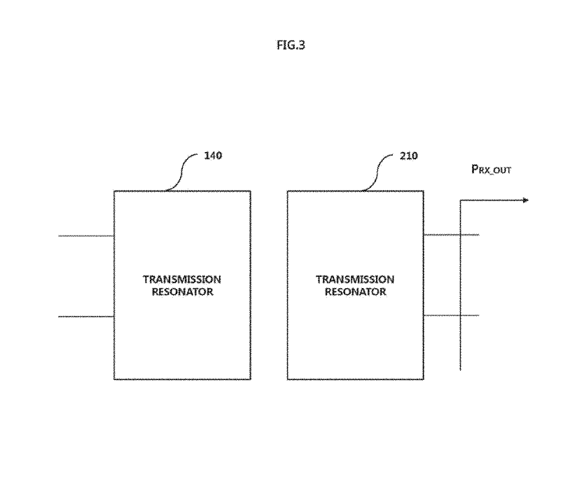

FIG. 2 is a diagram illustrating a type and characteristics of a wireless power transmitter in an electromagnetic resonance scheme according to an embodiment of the present disclosure.

Types and characteristics of the wireless power transmitter and the wireless power receiver according to the present disclosure may be classified into classes and categories.

The type and characteristics of the wireless power transmitter may be broadly identified by the following three parameters.

First, the wireless power transmitter may be identified by a class determined according to the intensity of the maximum power applied to the transmission resonator 140.

Here, the class of the wireless power transmitter may be determined by comparing the maximum value of the power P_{TX}_{_}_{IN}_{_}_{COIL} applied to the transmission resonator 140 with a predefined maximum input power for each class specified in a wireless power transmitter class table (hereinafter referred to as Table 1). Here, P_{TX}_{_}_{IN}_{_}_{COIL} may be an average real number value calculated by dividing the product of the voltage V(t) and the current I(t) applied to the transmission resonator 140 for a unit time by the unit time.

TABLE 1

| | | Minimum | |
|---|---|---|---|
| | | category | Maximum number |
| | Maximum input | support | of supportable |
| Class | power | requirements | devices |
| Class 1 | 2 W | 1 x Class 1 | 1 x Class 1 |
| Class 2 | 10 W | 1 x Class 3 | 2 x Class 2 |
| Class 3 | 16 W | 1 x Class 4 | 2 x Class 3 |
| Class 4 | 33 W | 1 x Class 5 | 3 x Class 3 |
| Class 5 | 50 W | 1 x Class 6 | 4 x Class 3 |
| Class 6 | 70 W | 1 x Class 6 | 5 x Class 3 |

The classes shown in Table 1 are merely an embodiment, and new classes may be added or existing classes may be deleted. It should also be noted that the maximum input power for each class, the minimum category support requirements, and the maximum number of supportable devices may vary depending on the use, shape, and implementation of the wireless power transmitter.

For example, referring to Table 1, when the maximum value of the power P_{TX}_{_}_{IN}_{_}_{COIL} applied to the transmission resonator 140 is greater than or equal to the value of P_{TX}_{_}_{IN}_{_{MAX}} corresponding to Class 3 and less than the value of P_{TX}_{_}_{IN}_{_{MAX}} corresponding to Class 4, the class of the wireless power transmitter may be determined as Class 3.

Second, the wireless power transmitter may be identified according to the minimum category support requirements corresponding to the identified class.

Here, the minimum category support requirement may be a supportable number of wireless power receivers corresponding to the highest level category of the wireless power receiver categories which may be supported by the wireless power transmitter of the corresponding class. That is, the minimum category support requirement may be the minimum number of maximum category devices which may be supported by the wireless power transmitter. In this case, the wireless power transmitter may support wireless power receivers of all categories lower than or equal to the maximum category according to the minimum category requirement.

However, if the wireless power transmitter is capable of supporting a wireless power receiver of a category higher than the category specified in the minimum category support requirement, the wireless power transmitter may not be restricted from supporting the wireless power receiver.

For example, referring to Table 1, a wireless power transmitter of Class 3 should support at least one wireless power receiver of Category 5. Of course, in this case, the wireless power transmitter may support a wireless power receiver 200 that falls into a category lower than the category level corresponding to the minimum category support requirement.

It should also be noted that the wireless power transmitter may support a wireless power receiver of a higher level category if it is determined that the category whose level is higher than the category corresponding to the minimum category support requirement can be supported.

Third, the wireless power transmitter may be identified by the maximum number of supportable devices corresponding to the identified class. Here, the maximum number of supportable devices may be identified by the maximum number of supportable wireless power receivers corresponding to the lowest level category among the categories which are supportable in the class—hereinafter, simply referred to as the maximum number of supportable devices.

For example, referring to Table 1, the wireless power transmitter of Class 3 should support up to two wireless power receivers corresponding to Category 3 which is the lowest level category.

However, when the wireless power transmitter is capable of supporting more than the maximum number of devices corresponding to its own class, it is not restricted from supporting more than the maximum number of devices.

The wireless power transmitter according to the present disclosure must perform wireless power transmission within the available power for up to at least the number defined in Table 1 if there is no particular reason not to allow the power transmission request from the wireless power receivers.

In one example, if there is not enough available power to accept the power transmission request the wireless power transmitter may not accept a power transmission request from the wireless power receiver. Alternatively, it may control power adjustment of the wireless power receiver.

In another example, when the wireless power transmitter accepts a power transmission request, it may not accept a power transmission request from a corresponding wireless power receiver if the number of acceptable wireless power receivers is exceeded.

In another example, the wireless power transmitter may not accept a power transmission request from a wireless power receiver if the category of the wireless power receiver requesting power transmission exceeds a category level that is supportable in the class of the wireless power transmitter.

In another example, the wireless power transmitter may not accept a power transmission request of the wireless power receiver if the internal temperature thereof exceeds a reference value.

In particular, the wireless power transmitter according to the present disclosure may perform the power redistribution procedure based on the currently available power. The power redistribution procedure may be performed further considering at least one of a category, a wireless power reception state, a required power, a priority, and a consumed power of a wireless power receiver for power transmission, which will be described later.

Information on the at least one of the category, wireless power reception state, required power, priority, and consumed power of the wireless power receiver may be transmitted from the wireless power receiver to the wireless power transmitter through at least one control signal over an out-of-band communication channel.

Once the power redistribution procedure is completed, the wireless power transmitter may transmit the power redistribution result to the corresponding wireless power receiver via out-of-band communication.

The wireless power receiver may recalculate the estimated time required to complete charging based on the received power redistribution result and transmit the re-calculation result to the microprocessor of a connected electronic device. Subsequently, the microprocessor may control the display provided to the electronic device to display the recalculated estimated charging completion time. At this time, the displayed estimated charging completion time may be controlled so as to disappear after being displayed for a predetermined time.

According to another embodiment of the present disclosure, when the estimated time required to complete charging is recalculated, the microprocessor may control the recalculated estimated charging completion to be displayed together with information on the reason for re-calculation. To this end, the wireless power transmitter may also transmit the information on the reason for occurrence of power redistribution to the wireless power receiver when transmitting the power redistribution result.

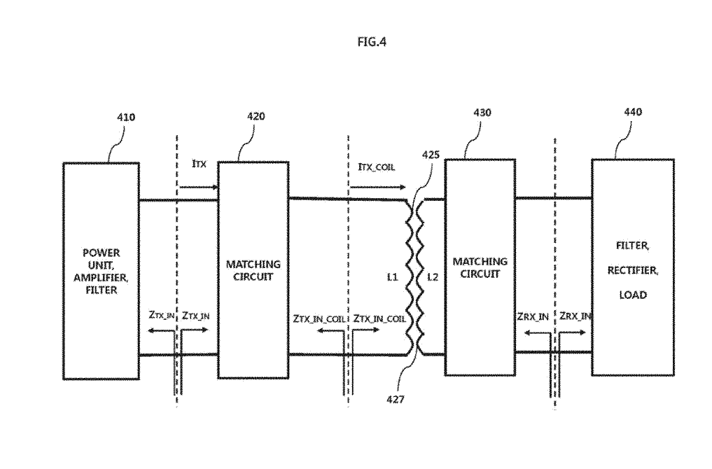

FIG. 3 is a diagram illustrating a type and characteristics of a wireless power receiver in an electromagnetic resonance scheme according to an embodiment of the present disclosure.

As shown in FIG. 3, the average output power P_{RX}_{_}_{OUT} of the reception resonator 210 is a real number value calculated by dividing the product of the voltage V(t) and the current I(t) output by the reception resonator 210 for a unit time by the unit time.

The category of the wireless power receiver may be defined based on the maximum output power P_{RX}_{_}_{OUT}_{_}_{MX} of the reception resonator 210, as shown in Table 2 below.

TABLE 2

| | Maximum input | | Application |
|---|---|---|---|
| Category | power | | example |
| Category 1 | TBD | | Bluetooth |
| | | | handset |
| Category 2 | 3.5 | W | Feature phone |
| Category 3 | 6.5 | W | Smartphone |
| Category 4 | 13 | W | Tablet |
| Category 5 | 25 | W | Small laptop |
| Category 6 | 37.5 | W | Laptop |
| Category 6 | 50 | W | TBD |

For example, if the charging efficiency at the load stage is 80% or more, the wireless power receiver of Category 3 may supply power of 5 W to the charging port of the load.

The categories disclosed in Table 2 are merely an embodiment, and new categories may be added or existing categories may be deleted. It should also be noted that the maximum output power for each category and application examples shown in Table 2 may vary depending on the use, shape and implementation of the wireless power receiver.

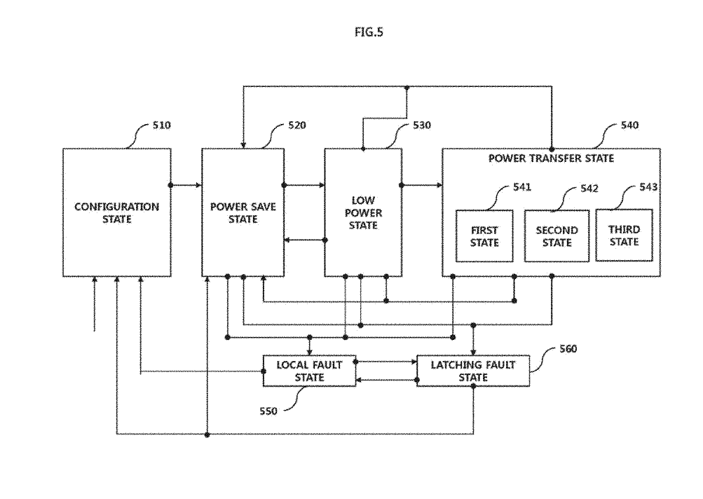

FIG. 4 shows equivalent circuit diagrams of a wireless power transmission system in an electromagnetic resonance scheme according to an embodiment of the present disclosure.

Specifically, FIG. 4 shows interface points on the equivalent circuit at which reference parameters, which will be described later, are measured.

Hereinafter, meanings of the reference parameters shown in FIG. 4 will be briefly described.

I_{TX} and I_{TX}_{_}_{COIL} denote the RMS (Root Mean Square) current applied to the matching circuit (or matching network) 420 of the wireless power transmitter and the RMS current applied to the transmission resonator coil 425 of the wireless power transmitter.

Z_{TX}_{_}_{IN} denotes the input impedance at the rear end of the power unit/amplifier/filter 410 of the wireless power transmitter and the input impedance at the front end of the matching circuit 420.

Z_{TX}_{_}_{IN}_{_}_{COIL} denotes the input impedance at the rear end of the matching circuit 420 and the front end of the transmission resonator coil 425.

L1 and L2 denote the inductance value of the transmission resonator coil 425 and the inductance value of the reception resonator coil 427, respectively.

Z_{RX}_{_}_{IN} denotes the input impedance at the rear end of the matching circuit 430 of the wireless power receiver and the front end of the filter/rectifier/load 440 of the wireless power receiver.

The resonant frequency used in the operation of the wireless power transmission system according to an embodiment of the present disclosure may be 6.78 MHz±15 kHz.

In addition, the wireless power transmission system according to an embodiment may provide simultaneous charging (i.e., multi-charging) for a plurality of wireless power receivers. In this case, even if a wireless power receiver is newly added or removed, the received power variation of the remaining wireless power receivers may be controlled so as not to exceed a predetermined reference value. For example, the received power variation may be ±10%, but embodiments are not limited thereto. If it is not possible to control the received power variation not to exceed the reference value, the wireless power transmitter may not accept the power transmission request from the newly added wireless power receiver.

The condition for maintaining the received power variation is that the existing wireless power receivers should not overlap a wireless power receiver that is added to or removed from the charging area.

When the matching circuit 430 of the wireless power receiver is connected to the rectifier, the real part of Z_{TX}_{_}_{IN} may be inversely proportional to the load resistance of the rectifier (hereinafter, referred to as R_{RECT}). That is, an increase in R_{RECT} may decrease Z_{TX}_{_}_{IN}, and a decrease in R_{RECT} may increase Z_{TX}_{_}_{IN}.

The resonator coupling efficiency according to the present disclosure may be a maximum power reception ratio calculated by dividing the power transmitted from the reception resonator coil to the load 440 by the power carried in the resonant frequency band in the transmission resonator coil 425. The resonator coupling efficiency between the wireless power transmitter and the wireless power receiver may be calculated when the reference port impedance Z_{TX}_{_}_{IN} of the transmission resonator and the reference port impedance Z_{RX}_{_}_{IN} of the reception resonator are perfectly matched.

Table 3 below is an example of the minimum resonator coupling efficiencies according to the classes of the wireless power transmitter and the classes of the wireless power receiver according to an embodiment of the present disclosure.

TABLE 3

| | Category | Category | Category | Category | Category | Category | Category |
|---|---|---|---|---|---|---|---|
| | 1 | 2 | 3 | 4 | 5 | 6 | 7 |
| Class | N/A | N/A | N/A | N/A | N/A | N/A | N/A |
| 1 | | | | | | | |
| Class | N/A | 74% | 74% | N/A | N/A | N/A | N/A |
| 2 | | (−1.3) | (−1.3) | | | | |
| Class | N/A | 74% | 74% | 76% | N/A | N/A | N/A |
| 3 | | (−1.3) | (−1.3) | (−1.2) | | | |
| Class | N/A | 50% | 65% | 73% | 76% | N/A | N/A |
| 4 | | (−3) | (−1.9) | (−1.4) | (−1.2) | | |
| Class | N/A | 40% | 60% | 63% | 73% | 76% | N/A |
| 5 | | (−4) | (−2.2) | (−2) | (−1.4) | (−1.2) | |
| Class | N/A | 30% | 50% | 54% | 63% | 73% | 76% |
| 5 | | (−5.2) | (−3) | (−2.7) | (−2) | (−1.4) | (−1.2) |

When a plurality of wireless power receivers is used, the minimum resonator coupling efficiencies corresponding to the classes and categories shown in Table 3 may increase.

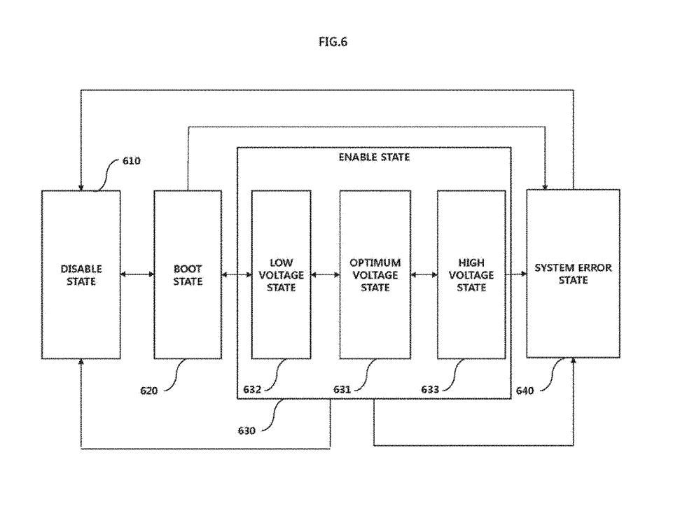

FIG. 5 is a state transition diagram illustrating a state transition procedure of a wireless power transmitter that supports the electromagnetic resonance scheme according to an embodiment of the present disclosure.

Referring to FIG. 5, the states of the wireless power transmitter may include a configuration state 510, a power save state 520, a low power state 530, a power transfer state 540, a local fault state 550, and a latching fault state 560.

When power is applied to the wireless power transmitter, the wireless power transmitter may transition to the configuration state 510. The wireless power transmitter may transition to a power save state 520 when a predetermined reset timer expires in the configuration state 510 or the initialization procedure is completed.

In the power save state 520, the wireless power transmitter may generate a beacon sequence and transmit the same through a resonant frequency band.

Here, the wireless power transmitter may control the beacon sequence to be initiated within a predetermined time after entering the power save state 520. For example, the wireless power transmitter may control the beacon sequence to be initiated within 50 ms after transition to the power save state 520. However, embodiments are not limited thereto.

In the power save state 520, the wireless power transmitter may periodically generate and transmit a first beacon sequence for sensing a wireless power receiver, and sense change in impedance of the reception resonator, that is, load variation. Hereinafter, for simplicity, the first beacon and the first beacon sequence will be referred to as a short beacon and a short beacon sequence, respectively.

In particular, the short beacon sequence may be repeatedly generated and transmitted at a constant time interval t_{CYCLE} during a short period t_{SHORT}_{_}_{BEACON} such that the standby power of the wireless power transmitter may be saved until a wireless power receiver is sensed. For example, t_{SHORT}_{_}_{BEACON} may be set to 30 ms or less, and t_{CYCLE} may be set to 250 ms±5 ms. In addition, the current intensity of the short beacon may be greater than a predetermined reference value, and may be gradually increased during a predetermined time period. For example, the minimum current intensity of the short beacon may be set to be sufficiently large such that a wireless power receiver of Category 2 or a higher category in Table 2 above may be sensed.

The wireless power transmitter according to the present disclosure may be provided with a predetermined sensing means for sensing change in reactance and resistance of the reception resonator according to the short beacon.

In addition, in the power save state 520, the wireless power transmitter may periodically generate and transmit a second beacon sequence for providing sufficient power necessary for booting and response of the wireless power receiver. Hereinafter, for simplicity, the second beacon and the second beacon sequence will be referred to as a long beacon and a long beacon sequence, respectively.

That is, the wireless power receiver may broadcast a predetermined response signal over an out-of-band communication channel when booting is completed through the second beacon sequence.

In particular, the long beacon sequence may be generated and transmitted at a constant time interval t_{LONG}_{_}_{BEACON}_{_}_{PERIOD} during a relatively long period t_{LONG}_{_}_{BEACON} compared to the short beacon to supply sufficient power necessary for booting the wireless power receiver. For example, t_{LONG}_{_}_{BEACON} may be set to 105 ms+5 ms, and t_{LONG}_{_}_{BEACON}_{_}_{PERIOD} may be set to 850 ms. The current intensity of the long beacon may be stronger than the current intensity of the short beacon. In addition, the long beacon may maintain the power of a certain intensity during the transmission period.

Thereafter, the wireless power transmitter may wait to receive a predetermined response signal during the long beacon transmission period after change in impedance of the reception resonator is sensed. Hereinafter, for simplicity, the response signal will be referred to as an advertisement signal. Here, the wireless power receiver may broadcast the advertisement signal in an out-of-band communication frequency band that is different from the resonant frequency band.

In one example, the advertisement signal may include at least one of message identification information for identifying a message defined in the out-of-band communication standard, a unique service or wireless power receiver identification information for identifying whether the wireless power receiver is legitimate or compatible with the wireless power transmitter, information about the output power of the wireless power receiver, information about the rated voltage/current applied to the load, antenna gain information about the wireless power receiver, information for identifying the category of the wireless power receiver, wireless power receiver authentication information, information about whether or not the overvoltage protection function is provided, and version information about the software installed on the wireless power receiver.

Upon receiving the advertisement signal, the wireless power transmitter may establish an out-of-band communication link with the wireless power receiver after transitioning from the power save state 520 to the low power state 530. Subsequently, the wireless power transmitter may perform the registration procedure for the wireless power receiver over the established out-of-band communication link. For example, if the out-of-band communication is Bluetooth low-power communication, the wireless power transmitter may perform Bluetooth pairing with the wireless power receiver and exchange at least one of the state information, characteristic information, and control information about each other via the paired Bluetooth link.

If the wireless power transmitter transmits a predetermined control signal for initiating charging via out-of-band communication, i.e., a predetermined control signal for requesting that the wireless power receiver transmit power to the load, to the wireless power receiver in the low power state 530, the state of the wireless power transmitter may transition from the low power state 530 to the power transfer state 540.

If the out-of-band communication link establishment procedure or registration procedure is not normally completed in the low power state 530, the wireless power transmitter may transition from the low power state 530 to the power save state 520.

A separate independent link expiration timer by which the wireless power transmitter may connect to each wireless power receiver may be driven, and the wireless power receiver may transmit a predetermined message for announcing its presence to the wireless power transmitter in a predetermined time cycle before the link expiration timer expires. The link expiration timer is reset each time the message is received. If the link expiration timer does not expire, the out-of-band communication link established between the wireless power receiver and the wireless power receiver may be maintained.

If all of the link expiration timers corresponding to the out-of-band communication link established between the wireless power transmitter and the at least one wireless power receiver have expired in the low power state 530 or the power transfer state 540, the wireless power transmitter may transition to the power save state 520.

In addition, the wireless power transmitter in the low power state 530 may drive a predetermined registration timer when a valid advertisement signal is received from the wireless power receiver. When the registration timer expires, the wireless power transmitter in the low power state 530 may transition to the power save state 520. At this time, the wireless power transmitter may output a predetermined notification signal notifying that registration has failed through a notification display means (including, for example, an LED lamp, a display screen, and a beeper) provided in the wireless power transmitter.

Further, in the power transfer state 540, when charging of all connected wireless power receivers is completed, the wireless power transmitter may transition to the low power state 530.

In particular, the wireless power receiver may allow registration of a new wireless power receiver in states other than the configuration state 510, the local fault state 550, and the latching fault state 560.

In addition, the wireless power transmitter may dynamically control the transmit power based on the state information received from the wireless power receiver in the power transfer state 540.

Here, the receiver state information transmitted from the wireless power receiver to the wireless power transmitter may include at least one of required power information, information on the voltage and/or current measured at the rear end of the rectifier, charge state information, information indicating the overcurrent, overvoltage and/or overheated state, and information indicating whether or not a means for cutting off or reducing power transferred to the load according to the overcurrent or the overvoltage is activated. The receiver state information may be transmitted with a predetermined periodicity or transmitted every time a specific event is generated. In addition, the means for cutting off or reducing the power transferred to the load according to the overcurrent or overvoltage may be provided using at least one of an ON/OFF switch and a Zener diode.

According to another embodiment, the receiver state information transmitted from the wireless power receiver to the wireless power transmitter may further include at least one of information indicating that an external power source is connected to the wireless power receiver by wire and information indicating that the out-of-band communication scheme has changed (e.g., the communication scheme may change from NFC (Near Field Communication) to BLE (Bluetooth Low Energy) communication).

According to another embodiment of the present disclosure, a wireless power transmitter may adaptively determine the intensity of power to be received by each wireless power receiver based on at least one of the currently available power of the power transmitter, the priority of each wireless power receiver, or the number of connected wireless power receivers. Here, the power intensity of each wireless power receiver may be determined as a share of power to be received with respect to the maximum power that may be processed by the rectifier of the corresponding wireless power receiver.

Thereafter, the wireless power transmitter may transmit, to the wireless power receiver, a predetermined power control command including information about the determined power intensity. Then, the wireless power receiver may determine whether power control can be performed based on the power intensity determined by the wireless power transmitter, and transmit the determination result to the wireless power transmitter through a predetermined power control response message.

According to another embodiment of the present disclosure, a wireless power receiver may transmit predetermined receiver state information indicating whether wireless power control can be performed according to a power control command of a wireless power transmitter before receiving the power control command.

The power transfer state 540 may be any one of a first state 541, a second state 542 and a third state 543 depending on the power reception state of the connected wireless power receiver.

In one example, the first state 541 may indicate that the power reception state of all wireless power receivers connected to the wireless power transmitter is a normal voltage state.

The second state 542 may indicate that the power reception state of at least one wireless power receiver connected to the wireless power transmitter is a low voltage state and there is no wireless power receiver which is in a high voltage state.

The third state 543 may indicate that the power reception state of at least one wireless power receiver connected to the wireless power transmitter is a high voltage state.

When a system error is sensed in the power save state 520, the low power state 530, or the power transfer state 540, the wireless power transmitter may transition to the latching fault state 560.

The wireless power transmitter in the latching fault state 560 may transition to either the configuration state 510 or the power save state 520 when it is determined that all connected wireless power receivers have been removed from the charging area.

In addition, when a local fault is sensed in the latching fault state 560, the wireless power transmitter may transition to the local fault state 550. Here, the wireless power transmitter in the local fault state 550 may transition back to the latching fault state 560 when the local fault is released.

On the other hand, in the case where the wireless power transmitter transitions from any one state among the configuration state 510, the power save state 520, the low power state 530, and the power transfer state 540 to the local fault state 550, the wireless power transmitter may transition to the configuration state 510 once the local fault is released.

The wireless power transmitter may interrupt the power supplied to the wireless power transmitter once it transitions to the local fault state 550. For example, the wireless power transmitter may transition to the local fault state 550 when a fault such as overvoltage, overcurrent, or overheating is sensed. However, embodiments are not limited thereto.

In one example, the wireless power transmitter may transmit, to at least one connected wireless power receiver, a predetermined power control command for reducing the intensity of power received by the wireless power receiver when overcurrent, overvoltage, or overheating is sensed.

In another example, the wireless power transmitter may transmit, to at least one connected wireless power receiver, a predetermined control command for stopping charging of the wireless power receiver when overcurrent, overvoltage, or overheating is sensed.

Through the above-described power control procedure, the wireless power transmitter may prevent damage to the device due to overvoltage, overcurrent, overheating, or the like.

If the intensity of the output current of the transmission resonator is greater than or equal to a reference value, the wireless power transmitter may transition to the latching fault state 560. The wireless power transmitter that has transitioned to the latching fault state 560 may attempt to make the intensity of the output current of the transmission resonator less than or equal to a reference value for a predetermined time. Here, the attempt may be repeated a predetermined number of times. If the latching fault state 560 is not released despite repeated execution, the wireless power transmitter may send, to the user, a predetermined notification signal indicating that the latching fault state 560 is not released, using a predetermined notification means. In this case, when all of the wireless power receivers positioned in the charging area of the wireless power transmitter are removed from the charging area by the user, the latching fault state 560 may be released.

On the other hand, if the intensity of the output current of the transmission resonator falls below the reference value within a predetermined time, or if the intensity of the output current of the transmission resonator falls below the reference value during the predetermined repetition, the latching fault state 560 may be automatically released. In this case, the wireless power transmitter may automatically transition from the latching fault state 560 to the power save state 520 to perform the sensing and identification procedure for a wireless power receiver again.

The wireless power transmitter in the power transfer state 540 may transmit continuous power and adaptively control the transmit power based on the state information on the wireless power receiver and predefined optimal voltage region setting parameters.

For example, the predefined optimal voltage region setting parameters may include at least one of a parameter for identifying a low voltage region, a parameter for identifying an optimum voltage region, a parameter for identifying a high voltage region, and a parameter for identifying an overvoltage region.

The wireless power transmitter may increase the transmit power if the power reception state of the wireless power receiver is in the low voltage region, and reduce the transmit power if the power reception state is in the high voltage region.

The wireless power transmitter may also control the transmit power to maximize power transmission efficiency.

The wireless power transmitter may also control the transmit power such that the deviation of the power required by the wireless power receiver is less than or equal to a reference value.

In addition, the wireless power transmitter may stop transmitting power when the output voltage of the rectifier of the wireless power receiver reaches a predetermined overvoltage region, namely, when overvoltage is sensed.

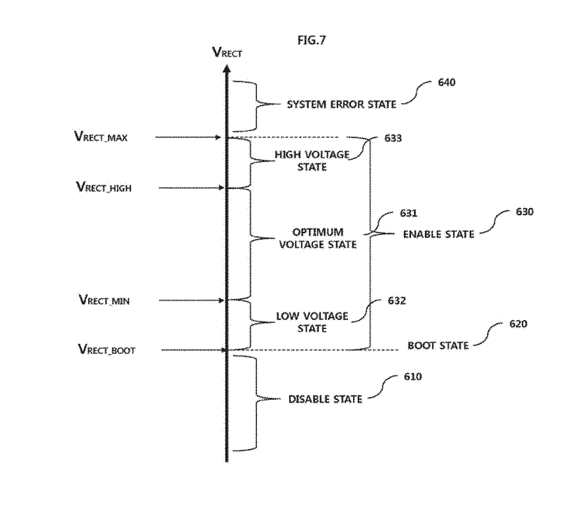

FIG. 6 is a state transition diagram illustrating a state transition procedure of a wireless power receiver in an electromagnetic resonance scheme according to an embodiment of the present disclosure.

Referring to FIG. 6, the states of the wireless power receiver may include a disable state 610, a boot state 620, an enable state (or on state) 630 and a system error state 640.

The state of the wireless power receiver may be determined based on the intensity of the output voltage at the rectifier end of the wireless power receiver (hereinafter referred to as V_{RECT} for simplicity).

The enable state 630 may be divided into an optimum voltage 631, a low voltage state 632 and a high voltage state 633 according to the value of V_{RECT}.

The wireless power receiver in the disable state 610 may transition to the boot state 620 if the measured value of V_{RECT} is greater than or equal to the predefined value of V_{RECT}_{_}_{BOOT}.

In the boot state 620, the wireless power receiver may establish an out-of-band communication link with a wireless power transmitter and wait until the value of V_{RECT} reaches the power required at the load stage.

When it is sensed that the value of V_{RECT} has reached the power required at the load stage, the wireless power receiver in the boot state 620 may transition to the enable state 630 and begin charging.

The wireless power receiver in the enable state 630 may transition to the boot state 620 when it is sensed that charging is completed or interrupted.

In addition, the wireless power receiver in the enable state 630 may transition to the system error state 640 when a predetermined system error is sensed. Here, the system error may include overvoltage, overcurrent, and overheating, as well as other predefined system error conditions.

In addition, the wireless power receiver in the enable state 630 may transition to the disable state 610 if the value of V_{RECT} falls below the value of V_{RECT}_{_}_{BOOT}.

In addition, the wireless power receiver in the boot state 620 or the system error state 640 may transition to the disable state 610 if the value of V_{RECT} falls below the value of V_{RECT}_{_}_{BOOT}.

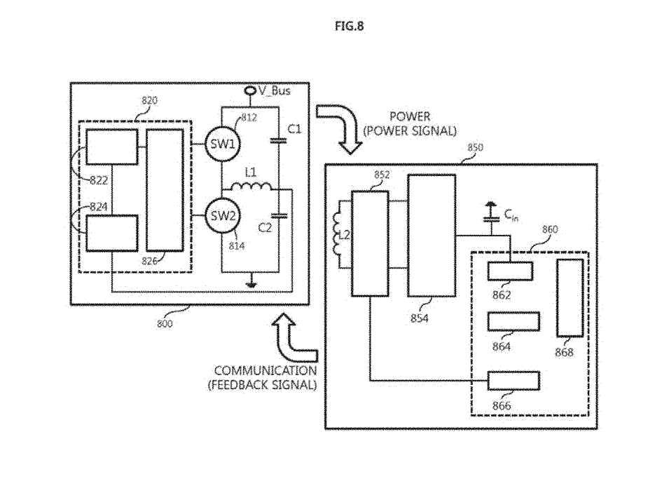

Hereinafter, state transition of the wireless power receiver in the enable state 630 will be described in detail with reference to FIG. 7.

FIG. 7 illustrates operation regions of a wireless power receiver according to V_{RECT} in an electromagnetic resonance scheme according to an embodiment of the present disclosure.

Referring to FIG. 7, if the value of V_{RECT} is less than a predetermined value of V_{RECT}_{_}_{BOOT}, the wireless power receiver is maintained in the disable state 610.

Thereafter, when the value of V_{RECT} is increased beyond V_{RECT}_{_}_{BOOT}, the wireless power receiver may transition to the boot state 620 and broadcast an advertisement signal within a predetermined time. Thereafter, when the advertisement signal is sensed by the wireless power transmitter, the wireless power transmitter may transmit a predetermined connection request signal for establishing an out-of-band communication link to the wireless power receiver.

Once the out-of-band communication link is normally established and successfully registered, the wireless power receiver may wait until the value of V_{RECT} reaches the minimum output voltage of the rectifier for normal charging (hereinafter referred to as V_{RECT}_{_}_{MIN} for simplicity).

If the value of V_{RECT} exceeds V_{RECT}_{_}_{MIN}, the wireless power receiver may transition from the boot state 620 to the enable state 630 and may begin charging the load.

If the value of V_{RECT} in the enable state 630 exceeds a predetermined reference value V_{RECT}_{_}_{MAX} for determining overvoltage, the wireless power receiver may transition from the enable state 630 to the system error state 640.

Referring to FIG. 7, the enable state 630 may be divided into the low voltage state 632, the optimum voltage 631 and the high voltage state 633 according to the value of V_{RECT}.

The low voltage state 632 may refer to a state in which V_{RECT}_{_}_{BOOT}≤V_{RECT}≤V_{RECT}_{_}_{MIN}, the optimum voltage state 631 may refer to a state in which V_{RECT}_{_}_{MIN}<V_{RECT}≤V_{RECT}_{_}_{HIGH}, and the high voltage state 633 may refer to a state in which V_{RECT H}<V_{RECT}≤V_{RECT}_{_}_{MAX}.

In particular, the wireless power receiver having transitioned to the high voltage state 633 may suspend the operation of cutting off the power supplied to the load for a predetermined time (hereinafter referred to as a high voltage state maintenance time for simplicity). The high voltage state maintenance time may be predetermined so as not to cause damage to the wireless power receiver and the load in the high voltage state 633.

When the wireless power receiver transitions to the system error state 640, it may transmit a predetermined message indicating occurrence of overvoltage to the wireless power transmitter through the out-of-band communication link within a predetermined time.

The wireless power receiver may also control the voltage applied to the load using an overvoltage interruption means provided to prevent damage to the load due to the overvoltage in the system fault state 630. Here, an ON/OFF switch and/or a Zener diode may be used as the overvoltage interruption means.

Although a method and means for coping with a system error in a wireless power receiver when overvoltage is generated and the wireless power receiver transitions to the system error state 640 have been described in the above embodiment, this is merely an embodiment. In other embodiments, the wireless power receiver may transition to the system error state due to overheating, overcurrent, and the like.

As an example, in the case where the wireless power receiver transitions to the system error state due to overheating, the wireless power receiver may transmit a predetermined message indicating the occurrence of overheating to the wireless power transmitter. In this case, the wireless power receiver may drive a cooling fan or the like to reduce the internally generated heat.

According to another embodiment of the present disclosure, a wireless power receiver may receive wireless power in conjunction with a plurality of wireless power transmitters. In this case, the wireless power receiver may transition to the system error state 640 if it is determined that the wireless power transmitter from which the wireless power receiver is determined to actually receive wireless power is different from the wireless power transmitter with which the out-of-band communication link is actually established.

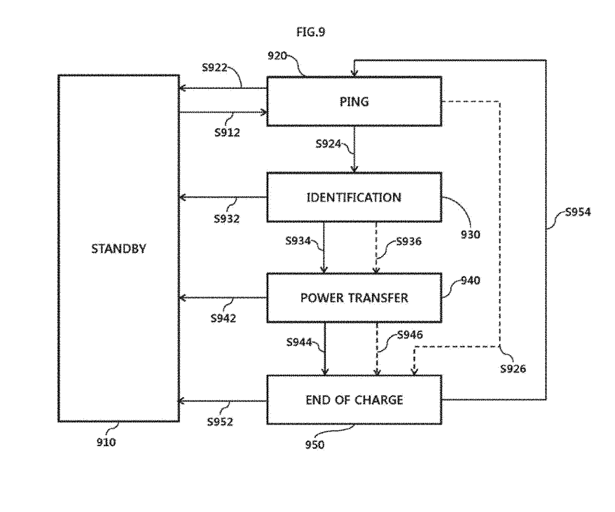

FIG. 8 is a diagram illustrating a wireless charging system of an electromagnetic induction scheme according to an embodiment of the present disclosure.

Referring to FIG. 8, a wireless charging system according to the electromagnetic induction scheme includes a wireless power transmitter 800 and a wireless power receiver 850. By placing an electronic device including the wireless power receiver 850 on the wireless power transmitter 800, the coils of the wireless power transmitter 800 and the wireless power receiver 850 may be coupled by an electromagnetic field.

The wireless power transmitter 800 may modulate a power signal and change the frequency to create an electromagnetic field for power transmission. The wireless power receiver 850 may receive power by demodulating the electromagnetic signal according to the protocol set to be suitable for the wireless communication environment and transmit a predetermined feedback signal to the wireless power transmitter 800 via in-band communication based on the intensity of the received power to control the intensity of the transmit power of the wireless power transmitter 800. For example, the wireless power transmitter 800 may control the operating frequency according to a control signal for power control to increase or decrease the transmit power.

The increase/decrease of power transmitted may be controlled using a feedback signal transmitted from the wireless power receiver 850 to the wireless power transmitter 800. Communication between the wireless power receiver 850 and the wireless power transmitter 800 is not limited to in-band communication using the feedback signal described above, but may also be performed using out-of-band communication provided with a separate communication module. For example, short-range wireless communication modules such as a Bluetooth module, a Bluetooth Low Energy (BLE) module, an NFC module, and a ZigBee module may be used.

In the electromagnetic induction scheme, a frequency modulation scheme may be used as a protocol for exchanging state information and control signals between the wireless power transmitter 800 and the wireless power receiver 850. The device identification information, the charging state information, the power control signal, and the like may be exchanged through the protocol.

As shown in FIG. 8, the wireless power transmitter 800 according to an embodiment of the present disclosure includes a signal generator 820 for generating a power signal, a coil L1 and capacitors C1 and C2 positioned between the power supply terminals V_Bus and GND capable of sensing a feedback signal transmitted from the wireless power receiver 850, and switches SW1 and SW2 whose operation is controlled by the signal generator 820. The signal generator 820 may include a demodulator 824 for demodulating a feedback signal transmitted through the coil L1, a frequency driver 826 for changing the frequency, and a transmission controller 822 for controlling the modulator 824 and the frequency driver 826. The feedback signal transmitted through the coil L1 may be demodulated by the demodulation unit 824 and then input to the transmission controller 822. The transmission controller 822 may control the frequency driver 826 based on the demodulated signal to change the frequency of the power signal transmitted through the coil L1.

The wireless power receiver 850 may include a modulator 852 for transmitting a feedback signal through a coil L2, a rectifier 854 for converting an AC signal received through the coil L2 into a DC signal, and a reception controller 860 for controlling the modulator 852 and the rectifier 854. The reception controller 860 may include a power supplier 862 for supplying power necessary for operation of the rectifier 854 and the wireless power receiver 850, and a DC-DC converter 864 for changing the DC output voltage of the rectifier 854 to a DC voltage satisfying the charging requirements of a charging target (a load 868), a load 868 for outputting the converted power, and a feedback communication unit 866 for generating a feedback signal for providing a receive power state and a charging target state to the wireless power transmitter 800.

The operation state of the wireless charging system supporting the electromagnetic induction scheme may be broadly classified into a standby state, a signal detection state, an identification state, a power transfer state, and an end-of-charge state. Transition to a different operation state may be performed according to a result of feedback communication between the wireless power receiver 850 and the wireless power transmitter 800. Transition between the standby state and the signal detection state may be performed using a predetermined receiver detection method for detecting presence of the wireless power receiver 850.

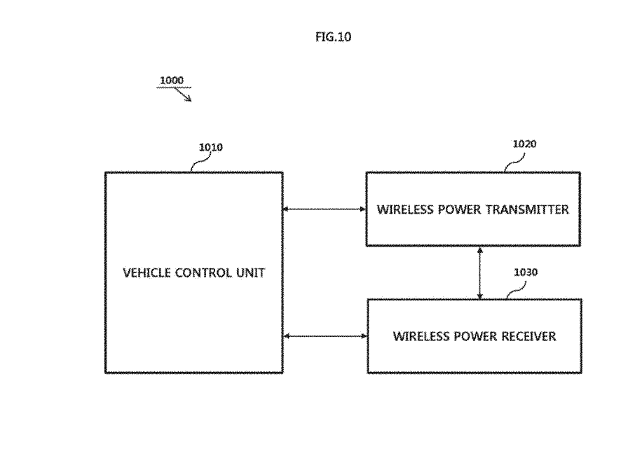

FIG. 9 is a state transition diagram of a wireless power transmitter supporting an electromagnetic induction scheme according to an embodiment of the present disclosure.

As shown in FIG. 9, the operation states of the wireless power transmitter may be broadly divided into a standby state (STANDBY) 910, a signal detection state (PING) 920, an identification state (IDENTIFICATION) 930, a power transfer state (POWER TRANSFER) 940 and an end-of-charge state (END OF CHARGE) 950.

Referring to FIG. 9, during the standby state 910, the wireless power transmitter monitors the charging area to sense if a chargeable reception device is positioned in the charging area. The wireless power transmitter may monitor change in magnetic field, capacitance, or inductance to sense a chargeable reception device. When a chargeable reception device is found, the wireless power transmitter may transition from the standby state 910 to the signal detection state 920 (S912).

In the signal detection state 920, the wireless power transmitter may connect to the chargeable reception device and check if the reception device is using a valid wireless charging technique. In addition, in the signal detection state 220, the wireless power transmitter may perform an operation to distinguish other devices that generate dark current (parasitic current).

In the signal detection state 920, the wireless power transmitter may also send a digital ping having a structure according to a predetermined frequency and time to connect to a chargeable reception device. If a sufficient power signal is transferred from the wireless power transmitter to the wireless power receiver, the wireless power receiver may respond by modulating the power signal according to the protocol set in the electromagnetic induction scheme. If a valid signal according to the wireless charging technique used by the wireless power transmitter is received, the wireless power transmitter may transition from the signal detection state 920 to the identification state 930 without interrupting transmission of the power signal (S924). A wireless power transmitter that does not support the operation in the identification state 930 may transition to the power transfer state 940 (S924 and S934).

If the wireless power transmitter receives an end-of-charge signal from the wireless power receiver, the wireless power transmitter may transition from the signal detection state 920 to the end-of-charge state 950 (S926).

If no response from the wireless power receiver is sensed in the signal detection state 920, for example, if no feedback signal is received for a predetermined time, the wireless power transmitter may interrupt transmission of the power signal and transition to the standby state 910 (S922).

The identification state 930 may be selectively included depending on the wireless power transmitter.

Unique receiver identification information may be pre-allocated and maintained for each wireless power receiver. When a digital ping is sensed, the wireless power receiver needs to inform the wireless power transmitter that the corresponding device is chargeable according to a specific wireless charging technique. To check such receiver identification information, the wireless power receiver may transmit unique identification information thereof to the wireless power transmitter through feedback communication.

A wireless power transmitter supporting the identification state 930 may determine validity of the receiver identification information sent from the wireless power receiver. If it is determined that the received receiver identification information is valid, the wireless power transmitter may transition to the power transfer state 940 (S936). If the received receiver identification information is not valid or validity is not determined within a predetermined time, the wireless power transmitter may interrupt transmission of the power signal and transition to the standby state 910 (S932).

In the power transfer state 940, the wireless power transmitter may control the intensity of the transmit power based on the feedback signal received from the wireless power receiver. In addition, the wireless power transmitter in the power transfer state 940 may verify that there is no violation of an acceptable operation region and tolerance limit that may arise, for example, by detection of a new device.

If a predetermined end-of-charge signal is received from the wireless power receiver in the power transfer state 940, the wireless power transmitter may stop transmitting the power signal and transition to the end-of-charge state 950 (S946). In addition, if the internal temperature exceeds a predetermined value during operation in the power transfer state 940, the wireless power transmitter may interrupt transmission of the power signal and may transition to the end-of-charge state 950 (S944).

In addition, if a system error or the like is sensed in the power transfer state 940, the wireless power transmitter may stop transmitting the power signal and transition to the standby state 910 (S942). A new charging procedure may be resumed when a reception device to be charged is sensed in the charging area of the wireless power transmitter.

As described above, the wireless power transmitter may transition to the end-of-charge state 950 when the end-of-charge signal is input from the wireless power receiver or the temperature exceeds a predetermined range during operation.

If transition to the end-of-charge state 950 is caused by an end-of-charge signal, the wireless power transmitter may interrupt transmission of the power signal and wait for a certain time. Here, the certain time may vary depending on components such as coils provided in the wireless power transmitter, the range of the charging area, the allowable limit of the charging operation, or the like, in order to transmit the power signal in the electromagnetic induction scheme. After a certain time elapses in the end-of-charge state 950, the wireless power transmitter may transition to the signal detection state 920 to connect to the wireless power receiver positioned on the charging surface (S954). The wireless power transmitter may also monitor the charging surface for a certain time to recognize whether the wireless power reception device is removed. If it is sensed that the wireless power reception device has been removed from the charging surface, the wireless power transmission device may transition to the standby state 910 (S952).

If transition to the end-of-charge state S950 is performed due to the internal temperature of the wireless power transmitter, the wireless power transmitter may interrupt power transmission and monitor change in internal temperature. If the internal temperature falls within a certain range or to a certain value, the wireless power transmitter may transition to the signal detection state 920 (S954). The temperature range or value for transitioning the state of the wireless power transmitter may vary depending on the technology and method for manufacturing the wireless power transmitter. While monitoring change in temperature, the wireless power transmitter may monitor the charging surface to recognize if the wireless power reception device is removed. If it is sensed that the wireless power reception device has been removed from the charging surface, the wireless power transmitter may transition to the standby state 910 (S952).

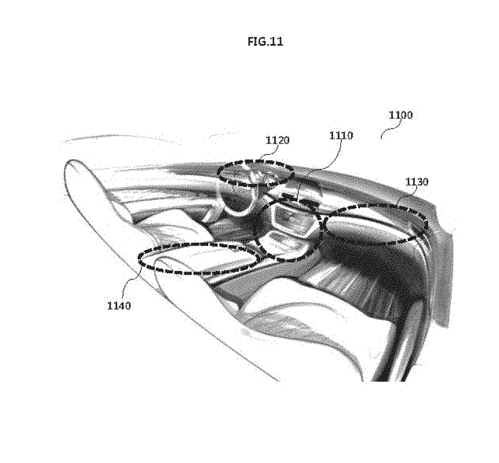

FIG. 10 is a block diagram illustrating a structure of a wireless charging system according to an embodiment of the present disclosure.

Referring to FIG. 10, a wireless charging system 1000 may include a vehicle control unit 1010, a wireless power transmitter 1020, and a wireless power receiver 1030. However, embodiments are not limited thereto.

The vehicle control unit 1010 may be mounted on a vehicle and control each element (e.g., an air conditioner) of the vehicle through intra-vehicle communication. The vehicle control unit 1010 may be connected to at least one of the wireless power transmitter 1020 and the wireless power receiver 1030, which perform a wireless charging operation, and may display a message corresponding to the charging state information related to the wireless charging operation.

The charging state information refers to information associated with the wireless charging operation for a specific wireless power receiver. For example, the charge state information may include charging connection information generated when the wireless power transmitter 1020 and the wireless power receiver 1030 are connected to each other and charging begins, an estimated time to complete charging of the wireless power receiver 1030, foreign matter sensing information (or foreign matter elimination information), which is information on introduction (or elimination) of foreign matter into (or from) the charging area, array correction information (or array correction complete information), which is information about whether the charging efficiency is abnormal (or normal), abnormal temperature information (abnormal temperature elimination information) generated when the temperature exceeds (or re-enters) a predetermined temperature range, and end-of-charge information generated when charging of the wireless power receiver 1030 is completed.

The charging state information may be generated by any one of the vehicle control unit 1010, the wireless power transmitter 1020, and the wireless power receiver 1030. The charging state information generated by the wireless power transmitter 1020 or the wireless power receiver 1030 may be directly transmitted to the vehicle control unit 1010 or may be transmitted to the vehicle control unit 1010 via another element. For example, the charging state information generated by the wireless power receiver 1030 may be transmitted to the vehicle control unit 1010 via the wireless power transmitter 1020.

State sensing information may be defined separately from the charging state information. The state sensing information may be information forming the basis of generation of the charging state information. The state sensing information will be described later in the description of each piece of the charging state information.

The wireless power transmitter 1020 may correspond to the wireless power transmitter 100 of FIG. 1 or the wireless power transmitter 800 of FIG. 8, and the description of FIG. or 8 is applied to the details of the wireless power transmitter 1020. Similarly, the wireless power receiver 1030 may correspond to the wireless power receiver 200 of FIG. 1 or the wireless power receiver 850 of FIG. 8. For details, refer to the description of FIG. 1 or 8.

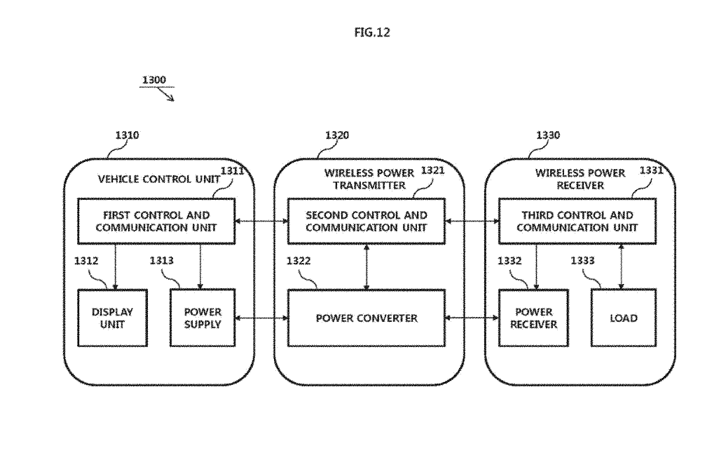

FIG. 11 is a view illustrating a position where the wireless power transmitter shown in FIG. 10 is installed in a vehicle.

Referring to FIGS. 10 and 11, the wireless charging system 1000 may be arranged inside the vehicle, and the vehicle control unit 1010 may be implemented as a part of the head unit of the vehicle.

The wireless power transmitter 1020 may be provided to any one of a center fascia 1110, a cluster top 1120, a passenger seat console box 1130, and a central console box 1140, but embodiments are not limited thereto. According to another embodiment, the wireless power transmitter 1020 may be provided at a plurality of positions.

The charging area referred to in FIG. 10 means an area where wireless power transmission from the wireless power transmitter 1020 to the wireless power receiver 1030 may take place. For example, when the wireless power transmitter 1020 is provided in the central console box 1140, the inside of the central console box 1140 may be the charging area.

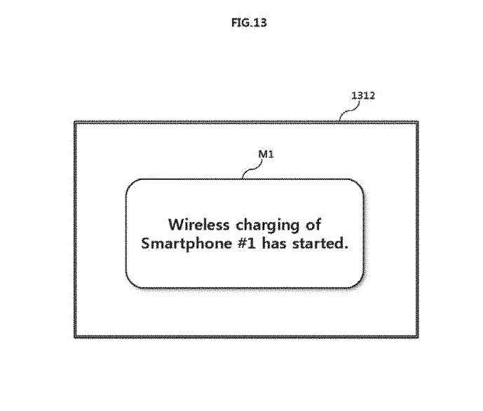

FIG. 12 is a block diagram illustrating an embodiment of the wireless charging system shown in FIG. 10. FIGS. 13 to 19 illustrate an example of messages that may be displayed on a display unit.

Referring to FIG. 12, the elements 1310, 1320 and 1330 of the wireless charging system 1300 correspond to the elements 1010, 1020 and 1030 having the same names shown in FIG. 10, respectively. Each of the elements 1310, 1320, and 1330 may be implemented in hardware, software, or a combination thereof.

The vehicle control unit 1310 may include a first control and communication unit 1311, a display unit 1312, and a power supply 1313.

The first control and communication unit 1311 may control the elements inside the vehicle control unit 1310 and may perform data communication with the outside of the vehicle control unit 1310. The first control and communication unit 1311 may generate a message corresponding to the charging state info/nation and transmit the same to the display unit 1312. In addition, the first control and communication unit 1311 may control the power supply 1313 to control power transmitted to the wireless power transmitter 1320.

The display unit 1312 may output various kinds of information related to the vehicle through a screen, and may be implemented with a display device such as an LCD. The display unit 1312 may receive the message corresponding to the charging state information from the first control and communication unit 1311 and display the message.

The power supply 1313 may supply power for the wireless charging operation and may be a battery for driving the vehicle.

The wireless power transmitter 1320 may include a second control and communication unit 1321 and a power converter 1322.

The second control and communication unit 1321 may control the elements inside the wireless power transmitter 1320 and perform data communication with the outside of the wireless power transmitter 1320. For example, the second control and communication unit 1321 may perform substantially the same functions as the main controller 150 and the communication unit 160 shown in FIG. 1. Alternatively, the second control and communication unit 1321 may perform or include the functions of the transmission controller 822 and the demodulator 824 in the wireless power transmitter 800 of FIG. 8. The power converter 1322 functions to receive power from the vehicle control unit 1310, convert the received power, and transmit the converted power to the wireless power receiver 1330. For example, the power converter 1322 may perform substantially the same functions as the power supplier 110, the power conversion unit 120, the matching circuit 130, and the transmission resonator 140 shown in FIG. 1.

The wireless power receiver 1330 may include a third control and communication unit 1331, a power receiver 1332, and a load 1333.

The third control and communication unit 1331 may control the elements inside the wireless power receiver 1330 and perform data communication with the outside of the wireless power receiver 1330. For example, the third control and communication unit 1331 may perform substantially the same functions as the main controller 250 and the communication unit 260 shown in FIG. 1. The third control and communication unit 1331 may include the reception controller 860 and the modulator 852 among the elements of the wireless power receiver 850 of FIG. 8, or include the main controller 250 and the communication unit 260 in the wireless power receiver of FIG. 1.

The power receiver 1332 functions to receive power from the wireless power transmitter 1320 in a wireless charging scheme (e.g., the electromagnetic resonance scheme or the electromagnetic induction scheme), convert the power, and transmit the converted power to the load 1333. For example, the power receiver 1332 may perform substantially the same functions as the reception resonator 210, the rectifier 220, and the DC-DC converter 230 shown in FIG. 1.

The load 1333 may be implemented as a rechargeable battery that accumulates the transmitted power, and may perform substantially the same function as the load 240 shown in FIG. 1.

Hereinafter, the operation of the wireless charging system 1300 related to wireless charging will be described with reference to FIGS. 13 to 19.

The vehicle control unit 1310 and the wireless power transmitter 1320 may be connected by a wired cable for data communication and power transmission. When the vehicle control unit 1310 is turned on, the wireless power transmitter 1320 may be turned on under control of the vehicle control unit 1310.

When preparation for wireless charging is completed through communication between the wireless power transmitter 1320 and the wireless power receiver 1330, wireless power transmission may be initiated between the wireless power transmitter 1320 and the wireless power receiver 1330. At this time, the wireless power transmitter 1320 may receive, from the wireless power receiver 1330, the charging start information, which is generated when connection between the wireless power transmitter 1320 and the wireless power receiver 1330 is established and charging begins, and receiver identification information for identifying the wireless power receiver 1330, generate charging connection information for announcing start of charging of the wireless power receiver 1330, and transmit the generated information to the first control and communication unit 1311. The first control and communication unit 1311 may generate a message corresponding to the charging connection information. Here, the charge start information is state sensing information, and the charge connection information is charging state information.

For example, if the receiver identification information indicates a smartphone assigned ID #1 (the first smartphone registered) and the charging start information indicates that wireless charging is started, the first control and communication unit 1311 may generate a message stating “Wireless charging of Smartphone #1 has started.”, and the display unit 1312 may display message M1 shown in FIG. 13. The content of messages M1 to M11 mentioned in this specification including message M1, may be output through a speaker (not shown) connected to the first control and communication unit 1311 as well as being displayed in order to reduce distraction of the driver of the vehicle.

After charging is initiated, the wireless power transmitter 1320 may receive receiver identification information and receiver power information from the wireless power receiver 1330 and may calculate an estimated time to complete charging of the wireless power receiver 1330 based on the receiver identification information and receiver power information, and generate estimated charging completion time information. The receiver power information includes information such as the total power capacity, the remaining power capacity and the average power consumption per unit time of the load 1333, load received power information, which is information about the power actually delivered to the load 1333, and current time information. When the smartphone equipped with the wireless power receiver 1330 is in use, the average power consumption per unit time is used to analyze the usage pattern of the smartphone and generate accurate estimated charging completion time information. Here, the receiver power information is state sensing information, and the estimated charging completion time information is charging state information.

The wireless power transmitter 1320 may communicate the estimated charging time information to the first control and communication unit 1311. The first control and communication unit 1311 may generate a message corresponding to the estimated charging completion time information.

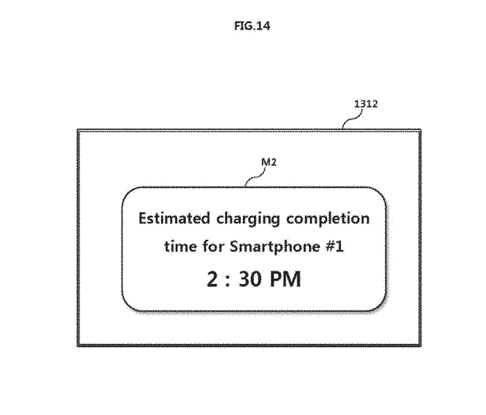

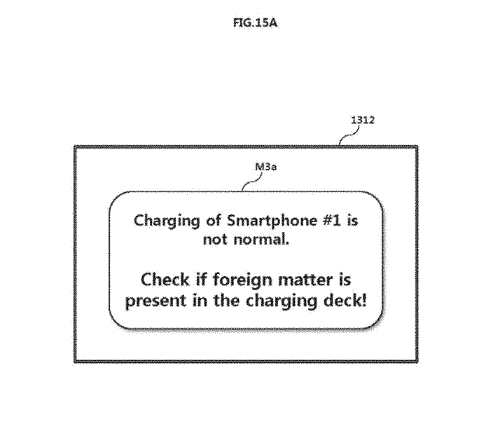

For example, if the receiver identification information indicates a smartphone assigned ID #1, and the estimated charging completion time information indicates that wireless charging will be completed at 2:30 PM, the first control and communication unit 1311 may generate a message stating “The estimated charging completion time for Smartphone #1 is 2:30 PM”, and the display unit 1312 may display the message M2 shown in FIG. 14. Here, if the charging completion estimated time information indicates that wireless charging will be completed three hours after the current time, the message M2 may be displayed with the phrase “after 3 hours” instead of “2:30 PM”.

The wireless power transmitter 1320 may periodically receive receiver identification information and receiver power information from the wireless power receiver 1330, or the wireless power receiver 1330 may receive a state change sensing report signal and transmit new receiver power information to the wireless power transmitter 1320. Then, the wireless power transmitter 1320 may recalculate the estimated time at which charging of the wireless power receiver 1330 will be completed, and generate new charging completion estimated time information, such that a corresponding message is displayed.

The state change sensing report signal may be transmitted from an electronic device (e.g., a smartphone) equipped with the wireless power receiver 1330, and may include at least one of information on a power ON/OFF state change of the electronic device, information on application execution, or information on change in power consumption of the electronic device.

Thus, a situation in which the estimated charging completion time is changed due to various causes during travel of the vehicle may be promptly sensed and the user may be notified of the same, such that the improper charging state can be corrected.

During charging, the wireless power transmitter 1320 may sense abnormal charging based on receiver identification information received from the wireless power receiver 1330, current receive power information, transmit power information, which is information on the transmit power of the power converter 1322, channel setting result information and/or change in impedance of the wireless power receiver 1330, and generate foreign matter sensing information or array correction information. Here, the current receive power information, the transmit power information, the channel setting result information, and the impedance change are state sensing information, and the foreign matter sensing information or the array correction information is charging state information.

The foreign matter sensing information is information indicating a case where abnormal charging occurs due to presence of foreign matter in the charging deck. The wireless power transmitter 1320 may sense an object through change in impedance, and then transmit a signal for channel setting. Then, the foreign matter sensing information may be generated according to channel setting result information, which is information on whether or not a feedback signal for the transmitted signal is received. If the channel setting result information indicates that feedback has not been received despite transmission of the signal for channel setting, the wireless power transmitter 1320 may determine, based on the channel setting result information, that the object is foreign matter.

The array correction information is information indicating a case where abnormal charging occurs when the wireless power receiver 1330 is at an incorrect position (particularly, out of a transmission range in the electromagnetic induction scheme). The array correction information may be generated when the power to be transmitted to the load 1333 as indicated by the current receive power information is significantly lower than the transmit power indicated by the transmit power information, or when the impedance of the wireless power receiver 1330 is out of a predetermined normal range. Here, the case where the power to be transmitted to the load is significantly lower than the transmit power indicated by the transmit power information may be predefined as a case where the power to be transmitted is less than or equal to a share (for example, 50%) of the transmit power, but embodiments are not limited thereto.

The wireless power transmitter 1320 may communicate the foreign matter sensing information or the array correction information to the first control and communication unit 1311. The first control and communication unit 1311 may generate a message corresponding to the foreign matter sensing information or the array correction information.

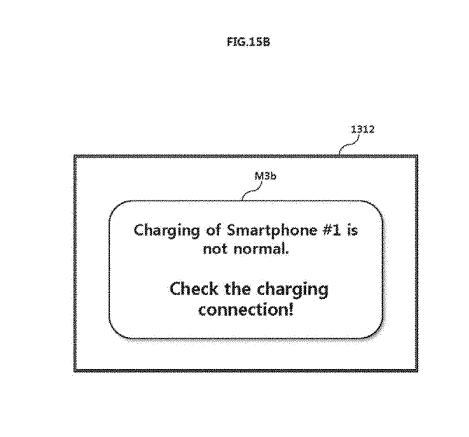

For example, if the receiver identification information indicates a smartphone assigned ID #1 (the first smartphone registered), and the foreign matter sensing information is delivered, the first control and communication unit 1311 may generate a message stating “Charging of Smartphone #1 is not normal. Check if foreign matter is present in the charging deck!”, and the display unit 1312 may display the message M3a shown in FIG. 15A.

If the receiver identification information indicates a smartphone assigned ID #1, and the array correction information is transmitted, the first control and communication unit 1311 may generate a message stating “Charging of Smartphone #1 is not normal. Check the charging connection!”, and the display unit 1312 may display the message M3b shown in FIG. 15B.

In an embodiment, the first control and communication unit 1311 may output a warning notification sound along with the message M3a, M3b, using a speaker (not shown) in the vehicle control unit 1310. The message M3a, M3b or the warning notification sound may be continuously output until abnormal charging resolution information, which will be described later, is received.

In addition, when abnormal charging is sensed, the wireless power transmitter 1320 may recalculate the estimated time at which charging of the wireless power receiver 1330 will be completed and generate new estimated charging completion time information such that a message for the generated information may be displayed together with the message M3a, M3b. Here, in displaying the messages, the two messages may be simultaneously displayed together on one screen or alternately displayed at a predetermined time interval. However, embodiments are not limited thereto.

When the user checks the message M3a, M3b and then removes foreign matter (e.g., conductive material) from the charging deck or restores the normal connection between the wireless power transmitter 1320 and the wireless power receiver 1330, the power transmitter 1320 may sense that the abnormal charging has been resolved and generate abnormal charging resolution information, and transmit the generated information to the first control and communication unit 1311. The first control and communication unit 1311 may generate a message corresponding to the abnormal charging resolution information. Here, the information (e.g., impedance change, current receive power information, etc.) for sensing that the abnormal charging has been resolved is state sensing information, and the abnormal charging resolution information is charging state information.

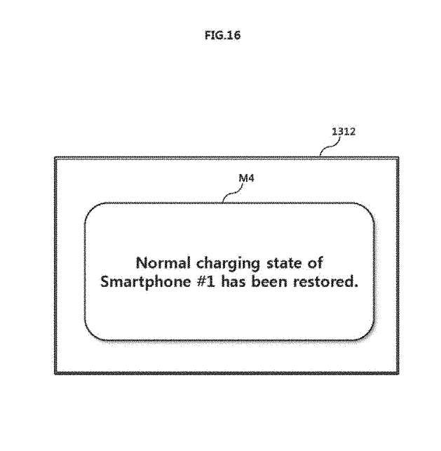

For example, if the receiver identification information indicates a smartphone assigned ID #1, and the abnormal charging resolution information is delivered, the first control and communication unit 1311 may generate a message stating “Normal charging state of Smartphone #1 has been restored”, and the display unit 1312 may display the message M4 shown in FIG. 16.

Further, as abnormal charging is resolved, the wireless power transmitter 1320 may recalculate an estimated time at which charging of the wireless power receiver 1330 is completed, generate new estimated charging completion time information, and cause the corresponding message M2 to be displayed.

During charging, the wireless power transmitter 1320 may sense an abnormal temperature based on the receiver identification information and temperature information received from the wireless power receiver 1330 to generate abnormal temperature information. For example, the abnormal temperature may be sensed when the temperature of the wireless power receiver 1330 exceeds a normal temperature range. Herein, the normal temperature range may be determined in consideration of the characteristics of the device equipped with the wireless power receiver 1330. However, embodiments are not limited thereto. The temperature information is state sensing information, and the abnormal temperature information is charging state information.

The wireless power transmitter 1320 may communicate the abnormal temperature information to the first control and communication unit 1311. The first control and communication unit 1311 may generate a message corresponding to the abnormal temperature information.

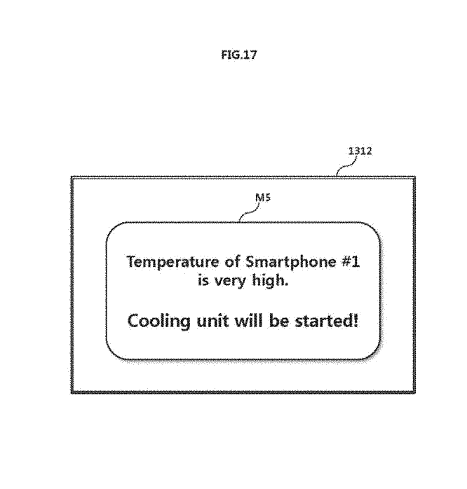

For example, if the receiver identification information is a smartphone with identification number 1, and the abnormal temperature information is transmitted, the first control and communication unit 1311 may generate a message stating “Temperature of Smartphone #1 is very high. Cooling unit will be started!”, and the display unit 1312 may display the message M5 shown in FIG. 17. According to an embodiment, the first control and communication unit 1311 may output a warning notification sound along with the message M5, using a speaker (not shown) in the vehicle control unit 1310. The message M5 or the warning notification sound may be continuously output until an abnormal temperature resolution signal, which will be described later, is received. The message M5 or the warning notification sound may be output at regular intervals so as not to interfere with the driving of the vehicle by the user, or may be stopped being output by manipulation of the user.

The first control and communication unit 1311 may control the operation of a cooling unit (not shown) provided to lower the temperature of the charging deck, and operate the cooling unit upon generating a message corresponding to the abnormal temperature information. A considerable amount of heat may be generated inside the vehicle during travel of the vehicle irrespective of the wireless charging operation. Accordingly, when the temperature of the charging deck rises above a certain temperature, the cooling unit may be operated automatically to prevent the device from being damaged.

When the temperature of the wireless power receiver 1330 returns to the normal temperature range due to operation of the cooling unit, the wireless power transmitter 1320 may sense, from the temperature information, that the abnormal temperature condition has been resolved, generate abnormal temperature resolution information, and transmit the generated information to the first control and communication unit 1311. The first control and communication unit 1311 may generate a message corresponding to the abnormal temperature resolution information. Here, the temperature information is state sensing information, and the abnormal temperature resolution information is charging state information.

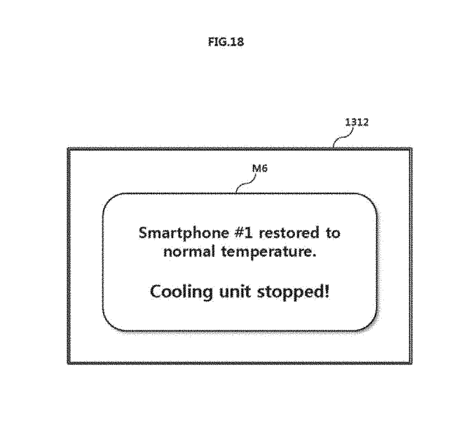

For example, if the receiver identification information indicates a smartphone assigned ID #1, and the abnormal charging resolution information is delivered, the first control and communication unit 1311 may generate a message stating “Smartphone #1 restored to normal temperature. Cooling unit stopped!”, and the display unit 1312 may display the message M6 shown in FIG. 18.

When the third control and communication unit 1331 of the wireless power receiver 1330 senses that charging of the load 1333 has been completed during monitoring of the charging state of the load 1333, it may generate receiver charging completion information and transmit the generated information to the second control and communication unit 1321. The second control and communication unit 1321 may generate charging completion information based on the receiver identification information and the receiver charging completion information and transmit the generated information to the first control and communication unit 1311. Here, the receiver charging completion information is state sensing information, and the charging completion information is charging state information.

The first control and communication unit 1311 may generate a message corresponding to the charging completion information.

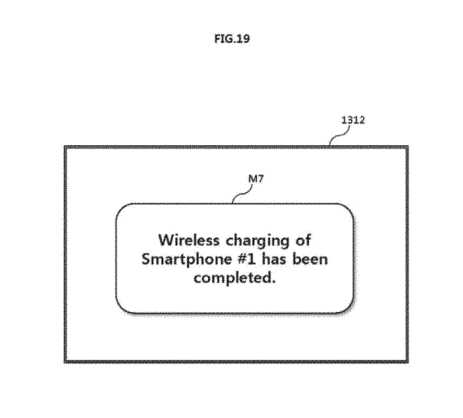

For example, if the receiver identification information indicates a smartphone assigned ID #1, and the charging completion information is delivered, the first control and communication unit 1311 may generate a message stating “Wireless charging of Smartphone #1 has been completed.”, and the display unit 1312 may display the message M7 shown in FIG. 19.

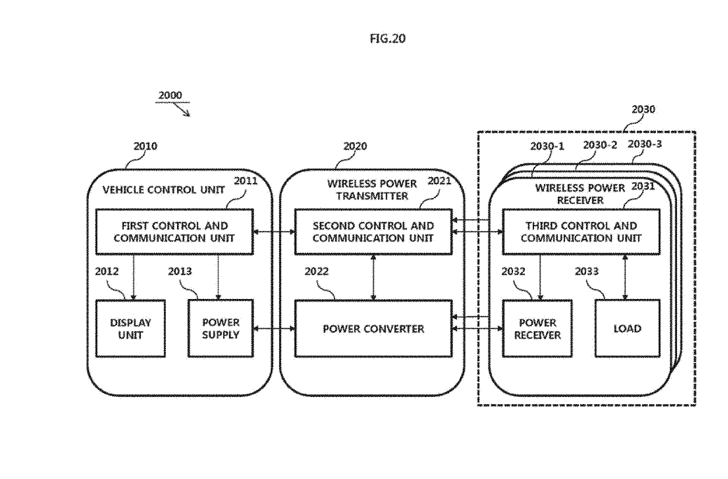

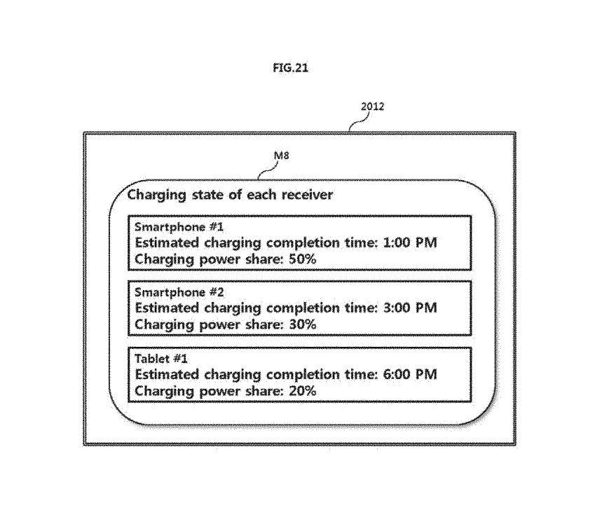

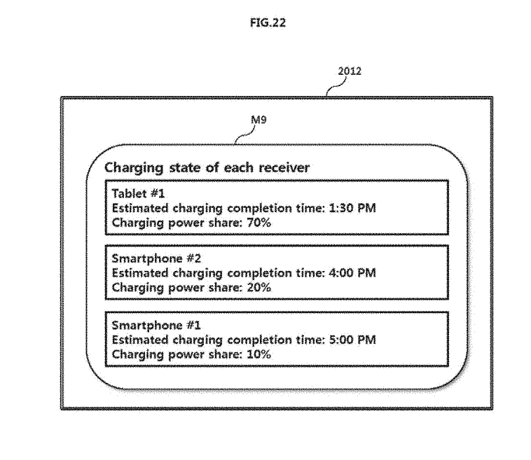

FIG. 20 is a block diagram illustrating another embodiment of the wireless charging system shown in FIG. 10. FIGS. 21 to 22 illustrate an example of messages that may be displayed on a display unit.

Referring to FIG. 20, the elements 2010, 2020, and 2030 of the wireless charging system 2000 correspond to the elements 1010, 1020, and 1030 having the same names and shown in FIG. 10, respectively. The configurations and operations of the elements 2010, 2020, and 2030 are substantially the same as the configurations and operations of the elements 1310, 1320, and 1330 shown in FIG. 12, respectively, and thus a detailed description thereof will be omitted. The wireless charging system 2000 includes a plurality of wireless power receivers 2030 and each of the wireless power receivers 2030-1 to 2030-3 is substantially the same as the wireless power receiver 1330 shown in FIG. 12.

While FIG. 20 illustrates that three wireless power receivers are included in the plurality of wireless power receivers 2030, embodiments are not limited thereto. Any number of wireless power receivers may be included.

Hereinafter, operation of the plurality of wireless power receivers 2030 will be mainly described.

Each of the wireless power receivers 2030-1 to 2030-3 may transmit/receive various kinds of information mentioned in the description of FIGS. 12 to 19 to/from the wireless power transmitter 2020.

In particular, after a plurality of wireless power receivers 2030-1 to 2030-3 is connected to the wireless power transmitter 2020 to initiate charging, the wireless power transmitter 2020 may receive receiver identification information and receiver power information from the wireless power receivers 2030-1 to 2030-3, calculate an estimated time at which charging of each of the wireless power receivers 2030-1 to 2030-3 is completed, based on the receiver identification information and the receiver power information, and generate estimated charging completion time information.

The wireless power transmitter 2020 may deliver the estimated charging completion time information about each wireless power receiver 2030-1 to 2030-3 to the first control and communication unit 2011. The first control and communication unit 2011 may generate a message corresponding to the estimated charging completion time information.

At this time, priority may be assigned to each of the three wireless power receivers 2030-1 to 2030-3. For example, the priority may be determined by the order of connection to the wireless power transmitter 2020, the type of the device equipped with the wireless power receivers 2030-1 to 2030-3, or the user's selection. Further, when the total transmit power of the wireless power transmitter 2020 is 100%, the charging power share assigned to each of the wireless power receivers 2030-1 to 2030-3 may be determined according to the priority. The wireless power transmitter 2020 may adjust the transmit power for each of the wireless power receivers 2030-1 to 2030-3 according to the charging power share.

The wireless power transmitter 2020 may transmit the priority information about each of the wireless power receivers 2030-1 to 2030-3 and the charging power share information about each of the wireless power receivers 2030-1 to 2030-3 together with the estimated charging completion time information about each of the wireless power receivers 2030-1 to 2030-3 to the first control and communication unit 2011. Here, the priority information and the charging power share information are charging state information.

In FIG. 21, it is assumed that that the wireless power receivers 2030-1 to 2030-3 are mounted in a smartphone assigned ID #1 (hereinafter referred to as a first smartphone), a smartphone assigned ID #2 (hereinafter referred to as a second smartphone), and a tablet assigned ID #1 (hereinafter referred to as a first tablet) and the priorities thereof are determined in the above listed order. It is also assumed that the estimated charging completion time and charging power share of the first smartphone are 1:00 PM and 50%, the estimated charging completion time and charging power share of the second smartphone are 3:00 PM and 30%, and the estimated charging completion time and charging power share of the first tablet are 6:00 PM and 20%.

The charging power shares may be omitted from the displayed information.

When the user desires to increase the charging speed of the first tablet and lower the charging speed of the first smartphone, the order of priorities of the first tablet and the first smartphone should be changed. In this case, the user may check the message M8 and perform an operation of changing the order of the priorities. For example, the order of priorities may be changed by dragging a box corresponding to the first smartphone and dropping the same at a position higher or lower than a box corresponding to the first tablet while the box corresponding to the first smartphone remains touched for a threshold time or more and dragging the box corresponding to the first smartphone and dropping the same at a position higher or lower than a box corresponding to the second tablet while the box corresponding to the first smartphone remains touched for a threshold time or more.

The first control and communication unit 2011 may communicate the priority change information about each of the wireless power receivers 2030-1 to 2030-3 according to the user's request to the wireless power transmitter 2020.

In this case, the wireless power transmitter 2020 may transmit the priority information and/or the charging power share information about each of the wireless power receivers 2030-1 to 2030-3 changed in accordance with the priority change information to the first control and communication unit 2011. Thus, the charging power shares of the first tablet and the first smartphone may be automatically changed to 50% and 20%, respectively.

Further, the user may perform an operation of checking the message M8 and directly changing the charging power shares. For example, the user may continuously touch the box corresponding to the first tablet to input “70”, and continuously touch the box corresponding to the first smartphone to input “10”.

The first control and communication unit 2011 may communicate the charging power share change information about each of the wireless power receivers 2030-1 to 2030-3 in accordance with the user's request to the wireless power transmitter 2020. In this case, the wireless power transmitter 2020 may transmit the priority information and charging power share information about each of the wireless power receivers 2030-1 to 2030-3 changed in accordance with the charging power share change information to the first control and communication unit 2011.

The message M9 shown in FIG. 22 shows that the priorities and the charging power shares corresponding to the message M8 are changed as the user directly changes the charging power shares.

When the charging power shares of the wireless power receivers 2030-1 to 2030-3 are changed, the current receive power information about each of the wireless power receivers 2030-1 to 2030-3 is changed. Accordingly, the wireless power transmitter 2020 may recalculate the estimated charging completion time information about the wireless power receivers 2030-1 to 2030-3 and transmit the recalculated information to the first control and communication unit 2011. The message M9 shown in FIG. 22 shows the estimated charging time of each of the wireless power receivers 2030-1 to 2030-3 according to the recalculated estimated charging completion time information.

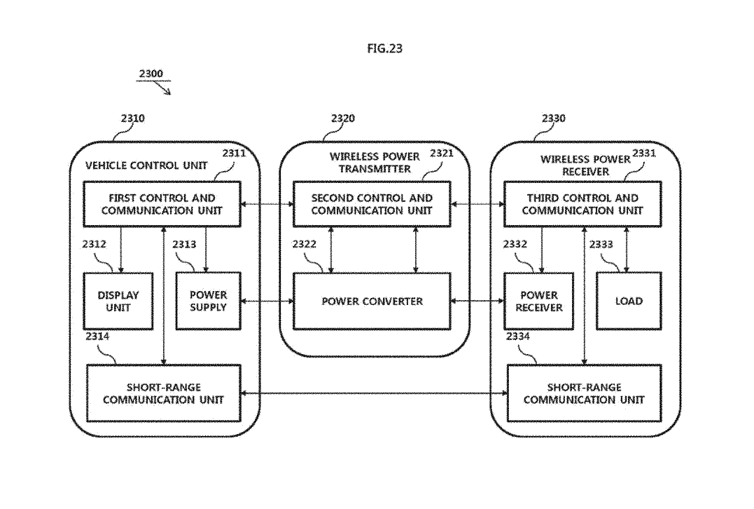

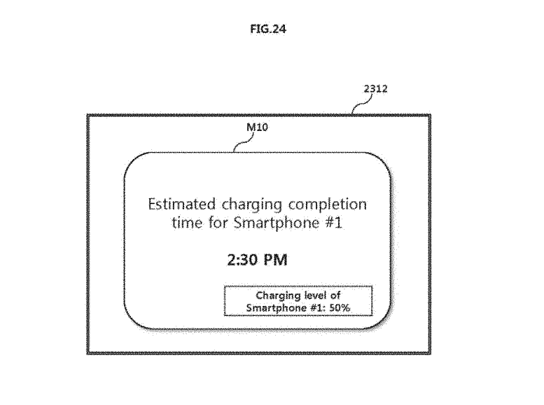

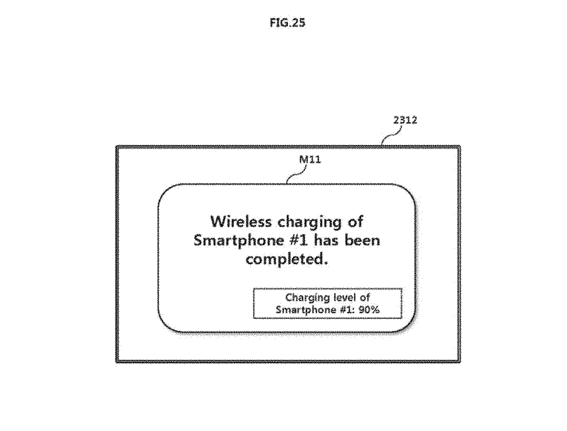

FIG. 23 is a block diagram illustrating another embodiment of the wireless charging system shown in FIG. 10. FIGS. 24 and 25 illustrate an example of messages that may be displayed on a display unit.

Referring to FIG. 23, the elements 2310, 2320, and 2330 of the wireless charging system 2300 correspond to the elements 1010, 1020, and 1030 having the same names and shown in FIG. 10, respectively. The configurations and operations of the elements 2310, 2320, and 2330 are substantially the same as the configurations and operations of the elements 1310, 1320, and 1330 shown in FIG. 12 except some configurations and operations, respectively, and thus a detailed description thereof will be omitted.

Each of the vehicle control unit 2310 and the wireless power receiver 2330 may include a short-range communication unit 2314, 2334. Each of the short-range communication units 2314 and 2334 may exchange data with each other using a short-range communication scheme. For example, the short-range communication scheme may be Bluetooth or NFC (Near Field Communication), but embodiments are not limited thereto.

The wireless power transmitter 2320 may transmit charging connection information and receiver identification information to the first control and communication unit 2311 when connected to the wireless power receiver 2330, and the first control and communication unit 2311 may attempt pairing with the wireless power receiver 2330 corresponding to the receiver identification information (the auto connection function).

Each short-range communication unit 2314, 2334 may relay data exchange between the first control and communication unit 2311 and the third control and communication unit 2331.

Hereinafter, a description will be given on the assumption that the first control and communication unit 2311 receives receiver power information from the wireless power receiver 2330 via the short-range communication units 2314 and 2334.

The first control and communication unit 2311 may recognize the total power capacity and the remaining power capacity of the load 2333 based on the receiver power information received from the wireless power receiver 2330 through the short-range communication units 2314 and 2334, thereby calculating a charging level of a corresponding device and generating remaining charging level information about the device. Here, the receiver power information is state sensing information, and the remaining charging level information is charging state information.

For example, the first control and communication unit 2311 may receive the estimated charging completion time information as shown in FIG. 14, and calculate a ratio of the remaining power capacity recognized from the receiver power information received via the short-range communication units 2314 and 2334 to the total power capacity. If the ratio is 50% as a result of the calculation, in addition to the message M2 of FIG. 14, the first control and communication unit 2311 may generate a message including the remaining charging level information, which is information on the charging level of the first smartphone, as well as the estimated charging completion time of the first smartphone. The display unit 2312 may display the message M10 shown in FIG. 24.

After receiving charging completion information, the first control and communication unit 2311 may calculate a ratio of the remaining power capacity recognized from the receiver power information received via the short-range communication units 2314 and 2334 to the total power capacity. If the ratio is 90% (a state in which the smartphone is discharged due to use thereof after being fully charged) as a result of the calculation, the first control and communication unit 2311 may generate a message including the remaining charging level information as well as the wireless charging completion message of the first smartphone in the message M7 of FIG. 19. The display unit 2312 may display the message M11 shown in FIG. 25. The user may check the actual current charging state of the first smartphone through the message M11, and instruct charging of the first smartphone to be resumed if necessary.

While it has been described herein that the charging state information related to the wireless charging operation is generated mainly by the wireless power transmitters 1320, 2020 and 2320, all or a part of the charging state information may be generated by the vehicle control unit 1310, 2010, 2310 or the wireless power receiver 1330, 2030, 2330 according to another embodiment.

For example, in FIG. 12, the wireless power receiver 1330 may calculate an estimated time at which charging of the wireless power receiver 1330 is completed based on the receiver identification information and the receiver power information, generate estimated charging completion time information, and transmit the generated information to the vehicle control unit 1310 via the power transmitter 1320. Alternatively, the vehicle control unit 1310 may receive the receiver identification information and the receiver power information via the wireless power transmitter 1320 and directly generate the estimated charging completion time information based thereon.

In a wireless charging system according to an embodiment, as various kinds of information related to the wireless charging operation are output through a vehicle control unit, a user may more safely and promptly recognize and cope with various changes in charging state that may occur in a travel environment of a vehicle.

In addition, even when a plurality of portable devices is charged, the wireless charging state of a plurality of portable devices may be monitored and controlled.

In addition, through direct communication between the vehicle control unit and the wireless power receiver, it is possible to provide a wider variety of information to the vehicle control unit.

It is apparent to those skilled in the art that the present disclosure may be embodied in specific forms other than those set forth herein without departing from the spirit and essential characteristics of the present disclosure. Therefore, the above embodiments should be construed in all aspects as illustrative and not restrictive. The scope of the disclosure should be determined by the appended claims and their legal equivalents, and all changes coming within the meaning and equivalency range of the appended claims are intended to be embraced therein.

The method according to embodiments of the present disclosure may be implemented as a program to be executed on a computer and stored in a computer-readable recording medium. Examples of the computer-readable recording medium include ROM, RAM, CD-ROM, magnetic tapes, floppy disks, and optical data storage devices, and also include carrier-wave type implementation (e.g., transmission over the Internet).

The computer-readable recording medium may be distributed to a computer system connected over a network, and computer-readable code may be stored and executed thereon in a distributed manner. Functional programs, code, and code segments for implementing the method described above may be easily inferred by programmers in the art to which the embodiments pertain.

It is apparent to those skilled in the art that the present disclosure may be embodied in specific forms other than those set forth herein without departing from the spirit and essential characteristics of the present disclosure.

Therefore, the above embodiments should be construed in all aspects as illustrative and not restrictive. The scope of the disclosure should be determined by the appended claims and their legal equivalents, and all changes coming within the meaning and equivalency range of the appended claims are intended to be embraced therein.

### INDUSTRIAL APPLICABILITY

The present disclosure relates to wireless charging technology and may be applied to a wireless power transmission apparatus that wirelessly transmits power.

1. A vehicle control unit connected to at least one of a wireless power transmitter performing a wireless charging operation or a wireless power receiver,
wherein the vehicle control unit displays a message corresponding to charging state information generated based on state sensing information related to the wireless charging operation.

2. The vehicle control unit according to claim 1, wherein the state sensing information comprises total power capacity information, remaining power capacity information and load receive power information about a load of the wireless power receiver,
wherein the charging state information comprises estimated charging completion time information indicating an estimated time at which charging of the wireless power receiver is completed, the estimated charging completion time information being calculated based on the total power capacity information, the remaining power capacity information, and the load receive power information.

3. The vehicle control unit according to claim 1, wherein the state sensing information comprises channel setting result information and an impedance change, the channel setting result information being information on whether a feedback signal is received by transmitting a signal for channel setting,
wherein the charging state information comprises foreign matter sensing information indicating corresponding to the channel setting result information indicating that the feedback signal has not been received even though the impedance change has occurred.

4. The vehicle control unit according to claim 1, wherein the state sensing information comprises transmit power information about the wireless power transmitter and current receive power information about the wireless power receiver,
wherein the charging state information comprises array correction information, the array correction information being generated when a ratio of the current receive power information to the transmit power information is out of a normal range.

5. The vehicle control unit according to claim 1, wherein the state sensing information comprises temperature information about the wireless power transmitter,
wherein the charging state information comprises abnormal temperature information, the abnormal temperature information being generated when a temperature of the wireless power receiver according to the temperature information is out of a normal temperature range.

6. The vehicle control unit according to claim 5, wherein, when the abnormal temperature information is received, the vehicle control unit activates a cooling unit configured to reduce the temperature of the wireless power receiver according to the abnormal temperature information,
wherein, when the temperature of the wireless power receiver returns to the normal temperature range, the vehicle control unit stops operation of the cooling unit.

7. The vehicle control unit according to claim 1, wherein the state sensing information comprises charging start information generated when connection between the wireless power transmitter and the wireless power receiver is established,
wherein the charging state information comprises charging connection information generated based on the charging start information and receiver identification information about the wireless power receiver.

8. The vehicle control unit according to claim 1, wherein the charging state information is generated by the wireless power transmitter based on the state sensing information provided by wireless power receiver and received from the wireless power transmitter,
generated by the vehicle control unit based on the state sensing information received from the wireless power receiver, or
generated by and received from the wireless power receiver.

9. The vehicle control unit according to claim 1, wherein the vehicle control unit is connected with the wireless power receiver in a short-range communication scheme.

10. A vehicle control unit connected to at least one of a wireless power transmitter performing a wireless charging operation or a plurality of wireless power receivers,
wherein the vehicle control unit displays a message corresponding to charging state information generated based on state sensing information related to the wireless charging operation.

11. The vehicle control unit according to claim 10, wherein the state sensing information comprises total power capacity information, remaining power capacity information and load receive power information about loads of the wireless power receivers,
wherein the charging state information comprises estimated charging completion time information indicating an estimated time at which charging of the wireless power receivers is completed, the estimated charging completion time information being calculated based on the total power capacity information, the remaining power capacity information, and the load receive power information.

12. The vehicle control unit according to claim 10, wherein the state sensing information comprises channel setting result information and an impedance change, the channel setting result information being information on whether a feedback signal is received by transmitting a signal for channel setting,
wherein the charging state information comprises foreign matter sensing information indicating corresponding to the channel setting result information indicating that the feedback signal has not been received even though the impedance change has occurred.

13. The vehicle control unit according to claim 10, wherein the state sensing information comprises transmit power information about the wireless power transmitter and current receive power information about the wireless power receivers,
wherein the charging state information comprises array correction information, the array correction information being generated when a ratio of the current receive power information to the transmit power information is out of a normal range.

14. The vehicle control unit according to claim 10, wherein the state sensing information comprises temperature information about the wireless power transmitter,
wherein the charging state information comprises abnormal temperature information, the abnormal temperature information being generated when a temperature of the wireless power receivers according to the temperature information is out of a normal temperature range.

15. The vehicle control unit according to claim 14, wherein, when the abnormal temperature information is received, the vehicle control unit activates a cooling unit configured to reduce the temperature of the wireless power receivers according to the abnormal temperature information,
wherein, when the temperature of the wireless power receivers returns to the normal temperature range, the vehicle control unit stops operation of the cooling unit.

16. The vehicle control unit according to claim 10, wherein the state sensing information comprises charging start information generated when connection between the wireless power transmitter and the wireless power receivers is established,
wherein the charging state information comprises charging connection information generated based on the charging start information and receiver identification information about the wireless power receivers.

17. The vehicle control unit according to claim 10, wherein the charging state information is generated by the wireless power transmitter based on the state sensing information provided by wireless power receivers and received from the wireless power transmitter,
generated by the vehicle control unit based on the state sensing information received from the wireless power receivers, or
generated by and received from the wireless power receivers.

18. The vehicle control unit according to claim 10, wherein the vehicle control unit displays an estimated charging completion time and a charging power share of each of the plurality of wireless power receivers in a priority order,
wherein the vehicle control unit requests that the charging power share be changed so as to correspond to a priority changed as the priority order is changed, or requests that the priority order be changed so as to correspond to a charging power share changed as the charging power share is changed.

19. The vehicle control unit according to claim 10, wherein the vehicle control unit is connected with the wireless power receivers in a short-range communication scheme.

20. A wireless power transmitter configured to:
generate charging state information based on state sensing information related to a wireless charge operation performed on a wireless power receiver; and
transmit the charging state information to a vehicle control unit such that a message corresponding to the charging state information is displayed.
